(19) United States
(12) Patent Application Publication
(10) Pub. No.: US 2025/0087293 A1
(43) Pub. Date: Mar. 13, 2025

(54) MEMORY MODULE, OPERATING METHOD OF MEMORY MODULE, AND MEMORY SYSTEM INCLUDING MEMORY MODULE

(71) Applicant: SAMSUNG ELECTRONICS CO., LTD., Suwon-si (KR)

(72) Inventors: JINSEONG YUN, Suwon-si (KR); Daehyun KWON, Suwon-si (KR); KI-HEUNG KIM, Suwon-si (KR); JONGHOON KIM, Suwon-si (KR); Sunghak LEE, Suwon-si (KR); CHANG-YONG LEE, Suwon-si (KR)

(73) Assignee: SAMSUNG ELECTRONICS CO., LTD., Suwon-si (KR)

(21) Appl. No.: 18/883,687

(22) Filed: Sep. 12, 2024

(30) Foreign Application Priority Data
Sep. 12, 2023 (KR) 10-2023-0121319
May 14, 2024 (KR) 10-2024-0063088

(51) Int. Cl. G11C 29/56

(52) U.S. Cl. CPC G11C 29/56016; G11C 29/56004; G11C 2029/5602

(57) ABSTRACT

A memory module includes: a circuit board including a plurality of signal lines to which a command is applied; and a first memory device mounted on a first surface of the circuit board, connected to the plurality of signal lines, including a first mode register, and configured to: operate in a standard mode or a mirrored mode, based on a value set in the first mode register, set a value corresponding to the mirrored mode in the first mode register, based on a first command applied to the plurality of signal lines, wherein at least one bit of a plurality of command/address bits in the first command is swapped with at least one bit of a plurality of command/address bits in a second command.

### CROSS-REFERENCE TO RELATED APPLICATIONS

This application is based on and claims priority under 35 U.S.C. § 119 to Korean Patent Application Nos. 10-2023-0121319, filed on Sep. 12, 2023, and 10-2024-0063088, filed on May 14, 2024, in the Korean Intellectual Property Office, the disclosures of which are incorporated by reference herein in their entireties.

### BACKGROUND

### 1. Field

The disclosure relates to a memory module, an operating method of the memory module, and a memory system including the memory module, and more particularly, relate to a memory module including a mirror function, an operating method of the memory module, and a memory system including the memory module.

### 2. Description of Related Art

A memory device is used to store data and is classified as a volatile memory device or a nonvolatile memory device. The volatile memory device refers to a memory device which loses data stored therein when a power is turned off. A dynamic random access memory (DRAM) among volatile memory devices is used in various fields such as a mobile system, a server, and a graphics device.

The DRAM may be used in a memory module which is in the form of a dual in-line memory module (DIMM) where a plurality of chips is mounted on opposite surfaces of a circuit board. The DRAM chips mounted on the opposite surfaces may use command/address signals in common. In this case, a mirror function may be implemented in the DRAM chips such that the DRAM chips mounted on the opposite surfaces operate identically depending on the command/address signals applied to the DRAM chips.

In general, a DRAM chip may include a pin (hereinafter referred to as a “mirror pin”) associated with the mirror function and may operate in a standard mode or a mirrored mode depending on a signal applied to the mirror pin. A DRAM chip which operates in the standard mode may use values of command/address signals applied to the DRAM chip without modification, and a DRAM chip which operates in the mirrored mode may swap and use values of command/address signals applied to the DRAM chip.

### SUMMARY

The disclosure is directed to implement a mirror function without a mirror pin.

According to an aspect of the disclosure, a memory module includes: a circuit board including a plurality of signal lines to which a command is applied; and a first memory device mounted on a first surface of the circuit board, connected to the plurality of signal lines, including a first mode register, and configured to: operate in a standard mode or a mirrored mode, based on a value set in the first mode register, set a value corresponding to the mirrored mode in the first mode register, based on a first command applied to the plurality of signal lines, wherein at least one bit of a plurality of command/address bits in the first command is swapped with at least one bit of a plurality of command/address bits in a second command.

According to an aspect of the disclosure, a memory system includes: a memory module including a first memory device mounted on a first surface of a circuit board; and a memory controller operatively connected to the memory module, wherein the first memory device includes a first mode register and is configured to operate in a standard mode or a mirrored mode based on a value stored in the first mode register, wherein the circuit board includes a plurality of signal lines connected to the first memory device, wherein the memory controller is configured to apply, to the plurality of signal lines, a first command for setting a value corresponding to the mirrored mode in the first mode register, and wherein the first command is a command in which at least one bit of a plurality of command/address bits is swapped with at least one bit of a plurality of command/address bits in a second command.

According to an aspect of the disclosure, a method of a memory module including a first memory device mounted on one surface of a circuit board, the method includes: operating, at the first memory device, in a standard mode, based on a default value set in a first mode register in the first memory device; setting a value corresponding to a mirrored mode in the first mode register, based on a first command applied to a plurality of signal lines connected to the first memory device; and operating, at the first memory device, in the mirrored mode, based on the value corresponding to the mirrored mode set in the first mode register, wherein the circuit board includes the plurality of signal lines, and wherein the first command is a command in which at least one bit of a plurality of command/address bits is swapped with at least one bit of a plurality of command/address bits in a second command.

### BRIEF DESCRIPTION OF THE DRAWINGS

The above and other objects and features of the disclosure will become apparent by describing embodiments thereof with reference to the accompanying drawings”

FIG. 1A illustrates a memory module according to an embodiment of the disclosure;

FIG. 1B illustrates an example of a memory module of FIG. 1A;

FIG. 2A illustrates an arrangement of pins of a memory device according to an embodiment of the disclosure;

FIG. 2B illustrates an arrangement of pins of a memory device according to an embodiment of the disclosure;

FIG. 3A illustrates a vertical cross-sectional view of a memory module according to an embodiment of the disclosure;

FIG. 3B illustrates a location relationship between CA pins of first and second memory devices facing away from each other;

FIG. 4 illustrates a vertical cross-sectional view of a memory module according to an embodiment of the disclosure;

FIG. 5 illustrates a first command according to an embodiment of the disclosure;

FIG. 6 illustrates a vertical cross-sectional view of a memory module according to an embodiment of the disclosure;

FIG. 7 illustrates a memory device according to an embodiment of the disclosure;

FIG. 8A illustrates a command/address swap circuit according to an embodiment of the disclosure;

FIG. 8B illustrates an example of a unit command/address swap circuit of FIG. 8A;

FIG. 8C is a diagram illustrating an example of a unit command/address swap circuit of FIG. 8A;

FIG. 9 illustrates a partial configuration of a memory device according to an embodiment of the disclosure;

FIG. 10A illustrates an example of a fuse circuit including a nonvolatile memory region of FIG. 9;

FIG. 10B illustrates an example in which a nonvolatile memory region is implemented by using anti-fuse cells of a fuse array;

FIG. 11 illustrates an operating method of a memory module according to an embodiment of the disclosure;

FIG. 12 illustrates an operating method of a memory module according to an embodiment of the disclosure;

FIG. 13 illustrates a partial configuration of a memory device according to an embodiment of the disclosure;

FIG. 14 illustrates a memory system according to an embodiment of the disclosure; and

FIG. 15 illustrates a configuration of a memory module according to an embodiment of the disclosure.

### DETAILED DESCRIPTION

Hereinafter, one or more embodiments of the disclosure will be described in detail with reference to the accompanying drawings to such an extent that one skilled in the art to which the disclosure belongs may easily carry the disclosure.

The terms as used in the disclosure are provided to merely describe specific embodiments, not intended to limit the scope of other embodiments. Singular forms include plural referents unless the context clearly dictates otherwise. The terms and words as used herein, including technical or scientific terms, may have the same meanings as generally understood by those skilled in the art. The terms as generally defined in dictionaries may be interpreted as having the same or similar meanings as or to contextual meanings of the relevant art. Unless otherwise defined, the terms should not be interpreted as ideally or excessively formal meanings. Even though a term is defined in the disclosure, the term should not be interpreted as excluding embodiments of the disclosure under circumstances.

Before undertaking the detailed description below, it may be advantageous to set forth definitions of certain words and phrases used throughout the disclosure. The terms “include” and “comprise”, and the derivatives thereof refer to inclusion without limitation. The term “or” is an inclusive term meaning “and/or”. The phrase “associated with,” as well as derivatives thereof, refer to include, be included within, interconnect with, contain, be contained within, connect to or with, couple to or with, be communicable with, cooperate with, interleave, juxtapose, be proximate to, be bound to or with, have, have a property of, have a relationship to or with, or the like. The term “controller” (e.g., a memory controller) refers to any device, system, or part thereof that controls at least one operation. The functionality associated with any particular controller may be centralized or distributed, whether locally or remotely. The phrase “at least one of,” when used with a list of items, means that different combinations of one or more of the listed items may be used, and only one item in the list may be needed. For example, “at least one of A, B, and C” includes any of the following combinations: A, B, C, A and B, A and C, B and C, and A and B and C, and any variations thereof. As an additional example, the expression “at least one of a, b, or c” may indicate only a, only b, only c, both a and b, both a and c, both b and c, all of a, b, and c, or variations thereof. Similarly, the term “set” means one or more. Accordingly, the set of items may be a single item or a collection of two or more items.

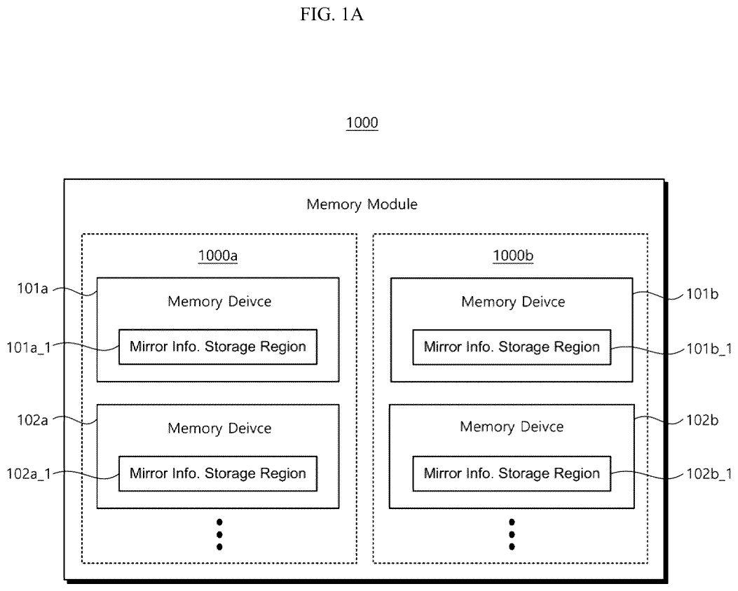

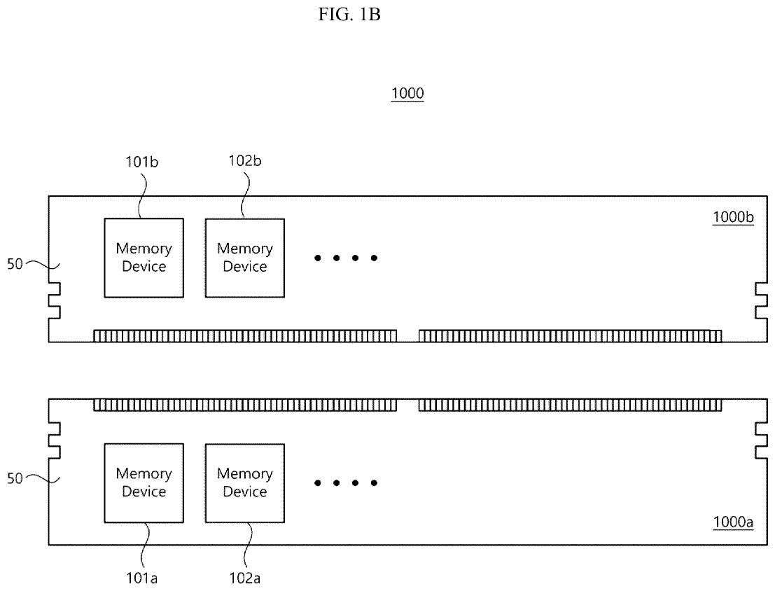

FIG. 1A illustrates a memory module according to an embodiment of the disclosure, and FIG. 1B is a diagram illustrating an example of a memory module of FIG. 1A.

Referring to FIGS. 1A and 1B, a memory module 1000 may include a circuit board 50, first memory devices 101a, 102a, . . . , etc. mounted on a first surface 1000a of the circuit board 50, and second memory devices 101b, 102b, . . . , etc. mounted on a second surface 1000b of the circuit board 50, which faces away from the first surface 1000a.

The number of first memory devices 101a, 102a, . . . , etc., the number of second memory devices 101b, 102b, . . . , etc., and the arrangement thereof may vary depending on the standard or specification of the memory module 1000. According to an embodiment, the memory module 1000 may be various kinds of dual in-line memory modules (DIMMs) complying with the joint electron device engineering council (JEDEC) standard. For example, the memory module 1000 may be a registered DIMM (RDIMM), a load reduced DIMM (LRDIMM), an unbuffered DIMM (UDIMM), a fully buffered DIMM (FB-DIMM), or a small outline DIMM (SO-DIMM). However, this is provided as an example, and the memory module 1000 may be a DIMM not complying with the JEDEC standard.

The first memory devices 101a, 102a, . . . , etc. and the second memory devices 101b, 102b, . . . , etc. may be mounted on the circuit board 50 so as to face away from each other. For example, the first memory device 101a and the second memory device 101b may be mounted on the circuit board 50 so as to face away from each other. Also, the first memory device 102a and the second memory device 102b may be mounted on the circuit board 50 so as to face away from each other. As in the above description, each of the remaining first memory devices and the remaining second memory devices may be mounted on the circuit board 50 so as to face away from each other.

In some embodiments, the first memory devices 101a, 102a, . . . , etc. and the second memory devices 101b, 102b, . . . , etc. may respectively include mirror information storage regions 101a_1, 102a_1, . . . , etc., 101b_1, 102b_1, . . . , etc. Each of the mirror information storage regions 101a_1, 102a_1, . . . , etc., 101b_1, 102b_1, . . . , etc. may store a value associated with the mirror function. For example, a first value corresponding to the standard mode or a second value corresponding to the mirrored mode may be stored, set, or programmed in each of the mirror information storage regions 101a_1, 102a_1, . . . , etc., 101b_1, 102b_1, . . . , etc. To this end, each of the mirror information storage regions 101a_1, 102a_1, . . . , etc., 101b_1, 102b_1, . . . , etc. may include at least one of a mode register or a nonvolatile memory.

Each of the first memory devices 101a, 102a, . . . , etc. and the second memory devices 101b, 102b, . . . , etc. may operate in the standard mode or the mirrored mode, based on the value set in the corresponding one of the mirror information storage regions 101a_1, 102a_1, . . . , etc., 101b_1, 102b_1, . . . , etc. For example, when the second value is set in each of the mirror information storage regions 101a_1, 102a_1, . . . , etc. of the first memory devices 101a, 102a, . . . , etc., and the first value is set in each of the mirror information storage regions 101b_1, 102b_1, . . . , etc. of the second memory devices 101b, 102b, . . . , etc., the first memory devices 101a, 102a, . . . , etc. may operate in the mirrored mode, and the second memory devices 101b, 102b, . . . , etc. may operate in the standard mode. However, the disclosure is not limited thereto.

According to an embodiment, a default value may be set in each of the mirror information storage regions 101a_1, 102a_1, . . . , etc., 101b_1, 102b_1, . . . , etc. Herein, the default value may be set in each of the mirror information storage regions 101a_1, 102a_1, . . . , etc., 101b_1, 102b_1, . . . , etc. The default value which is set in each of the mirror information storage regions 101a_1, 102a_1, . . . , etc., 101b_1, 102b_1, . . . , etc. may be maintained until a value different from the default value is set based on a first command to be described later.

In an embodiment, the default value may be determined in advance as one of the first value or the second value, in the process of manufacturing the memory devices 101a, 102a, . . . , etc., 101b, 102b, . . . , etc. Below, the first value is determined as the default value. Accordingly, when the default value is set in each of the mirror information storage regions 101a_1, 102a_1, . . . , etc., 101b_1, 102b_1, . . . , etc., all the first memory devices 101a, 102a, . . . , etc. and the second memory devices 101b, 102b, . . . , etc. may operate in the standard mode.

In some embodiments, the first memory devices 101a, 102a, . . . , etc. and the second memory devices 101b, 102b, . . . , etc. may use command/address (CA) signals applied through the circuit board 50 in common. For example, the circuit board 50 may include a plurality of signal lines to which a command is applied, and each of the first memory devices 101a, 102a, . . . , etc. and the second memory devices 101b, 102b, . . . , etc. may be connected to the plurality of signal lines. Accordingly, the first memory devices 101a, 102a, . . . , etc. and the second memory devices 101b, 102b, . . . , etc. may receive the command applied to the plurality of signal lines together and may operate based on the received command.

According to an embodiment, in this case, the connection of the CA pins of the first memory devices 101a, 102a, . . . , etc. with the plurality of signal lines may be different from the connection of the CA pins of the second memory devices 101b, 102b, . . . , etc. with the plurality of signal lines. Accordingly, the command applied to the plurality of signal lines may be differently received by the first memory devices 101a, 102a, . . . , etc., and the second memory devices 101b, 102b, . . . , etc. This will be described later. In this case, for the first memory devices 101a, 102a, . . . , etc. and the second memory devices 101b, 102b, . . . , etc. operates identically depending on the CA signals applied in common, the first memory devices 101a, 102a, . . . , etc. mounted on the first surface 1000a and the second memory devices 101b, 102b, . . . , etc. mounted on the second surface 1000b may operate in different modes in association with the mirror function.

In this regard, according to a first embodiment, when the second memory devices 101b, 102b, . . . , etc. operate in the standard mode and the first memory devices 101a, 102a, . . . , etc. operate in the mirrored mode, the first memory devices 101a, 102a, . . . , etc. and the second memory devices 101b, 102b, . . . , etc. may operate identically depending on the CA signals applied in common. Also, according to a second embodiment, when the first memory devices 101a, 102a, . . . , etc. operate in the standard mode and the second memory devices 101b, 102b, . . . , etc. operate in the mirrored mode, the first memory devices 101a, 102a, . . . , etc. and the second memory devices 101b, 102b, . . . , etc. may operate identically depending on the CA signals applied in common.

Whether either the first memory devices 101a, 102a, . . . , etc. or the second memory devices 101b, 102b, . . . , etc. operate in the mirrored mode may be determined depending on a connection relationship between pins of memory devices and the signal lines to which the CA signals are applied, which will be described later. Below, the case where the memory module 1000 corresponds to the first embodiment is described.

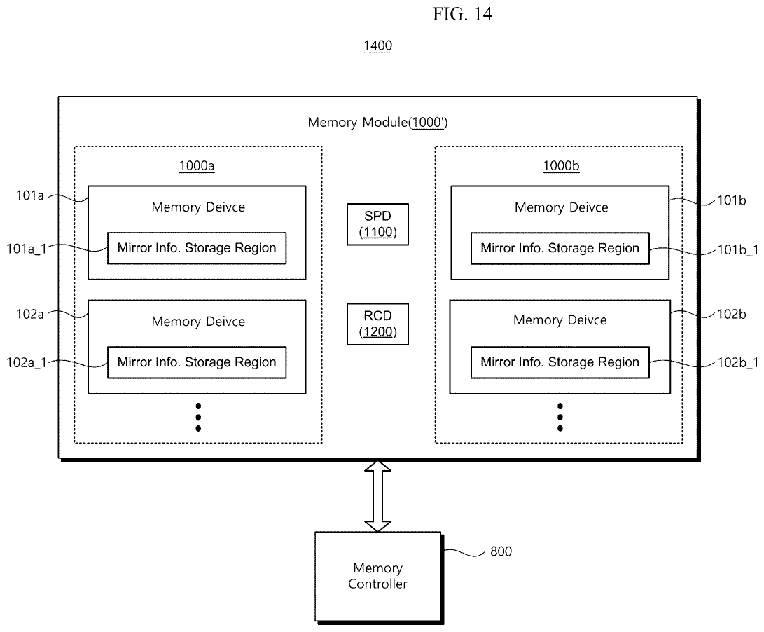

According to an embodiment, each of the first memory devices 101a, 102a, . . . , etc. may set the second value in each of the mirror information storage regions 101a_1, 102a_1, . . . , etc. For example, while the first memory devices 101a, 102a, . . . , etc. and the second memory devices 101b, 102b, . . . , etc. operate in the standard mode depending on the default value sets in the mirror information storage regions 101a_1, 102a_1, . . . , etc., 101b_1, 102b_1, . . . , etc., a memory controller 800 (refer to FIG. 14) may apply the first command to the plurality of signal lines. Accordingly, the first memory devices 101a, 102a, . . . , etc. may set the second values in the mirror information storage regions 101a_1, 102a_1, . . . , etc., respectively, based on the first command applied to the plurality of signal lines. In this case, a value set in each of the mirror information storage regions 101a_1, 102a_1, . . . , etc. of the first memory devices 101a, 102a, . . . , etc. may be changed from the default value to the second value.

Herein, the first command may be a command for setting the second value corresponding to the mirrored mode in the mirror information storage regions 101a_1, 102a_1, . . . , etc. of the first memory devices 101a, 102a, . . . , etc. According to an embodiment, the first command may be a command in which at least some of values of a plurality of CA bits included in a second command for setting the second value corresponding to the mirrored mode are swapped. For example, when the first command is the command in which at least some of the values of the plurality of CA bits included in the second command are swapped, the first command/address bit of the first command may have the same value as the second command/address bit of the second command, and the second command/address bit of the first command may have the same value as the first command/address bit of the second command. In an embodiment, at least one bit of a plurality of command/address bits in the first command is swapped with at least one bit of a plurality of command/address bits in the second command.

In an embodiment, when the first command is applied to the plurality of signal lines, each of the first memory devices 101a, 102a, . . . , etc. may receive the second command depending on the connection relationship between the CA pins and the plurality of signal lines. Each of the first memory devices 101a, 102a, . . . , etc. which are operating in the standard mode depending on the default value may set the second value in the mirror information storage regions 101a_1, 102a_1, . . . , etc. based on the received second command

When the second value is set in the mirror information storage regions 101a_1, 102a_1, . . . , etc. based on the first command, the first memory devices 101a, 102a, . . . , etc. may operate in the mirrored mode. In this case, the second memory devices 101b, 102b, . . . , etc. may maintain the standard mode. Accordingly, according to the first embodiment, the first memory devices 101a, 102a, . . . , etc. and the second memory devices 101b, 102b, . . . , etc. may operate identically depending on the CA signals applied in common.

According to the above embodiments of the disclosure, the mirror function may be implemented even though a mirror pin is absent from the memory devices 101a, 102a, . . . , etc., 101b, 102b, . . . , etc. That is, to transfer the second command to the first memory devices 101a, 102a, . . . , etc., which may operate in the mirrored mode, from among the first memory devices 101a, 102a, . . . , etc. and the second memory devices 101b, 102b, . . . , etc. currently operating in the standard mode, the memory controller 800 may apply the first command to the plurality of signal lines. When the first command where at least some of the values of the plurality of CA bits included in the second command are swapped is applied to the plurality of signal lines, the first memory devices 101a, 102a, . . . , etc. currently operating in the standard mode receive the second command through the plurality of signal lines, and the first memory devices 101a, 102a, . . . , etc. receiving the second command may set the second value corresponding to the mirrored mode in the mirror information storage regions 101a_1, 102a_1, . . . , etc. and may then operate in the mirrored mode.

In the above description, each of the first memory devices 101a, 102a, . . . , etc. and the second memory devices 101b, 102b, . . . , etc. may be a memory device which is based on a DRAM or a synchronous DRAM (SDRAM). In this case, according to an embodiment, each of the first memory devices 101a, 102a, . . . , etc. and the second memory devices 101b, 102b, . . . , etc. may include various types of memory elements such as an SDRAM memory element, a NAND flash memory element, a NOR flash memory element, a resistive RAM (RRAM) element, a ferroelectric RAM (FRAM) element, a phase change RAM (PRAM) element, a magnetoresistive RAM (MRAM) element, or a one-time programmable (OTP) memory element. Also, according to an embodiment, kinds of the first memory devices 101a, 102a, . . . , etc. and the second memory devices 101b, 102b, . . . , etc. may be identical to each other or may be different from each other.

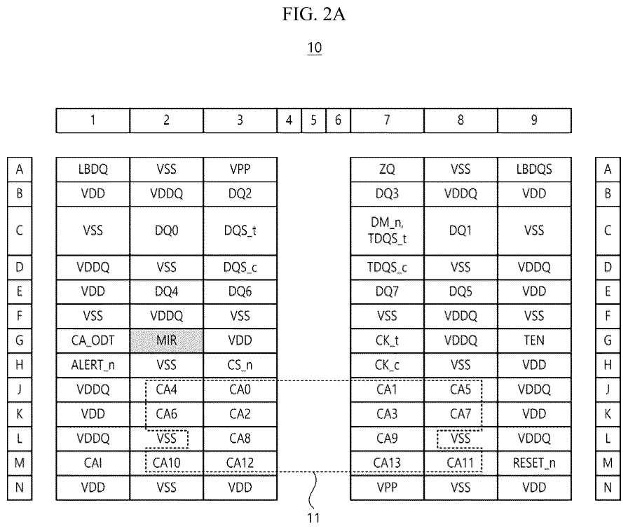

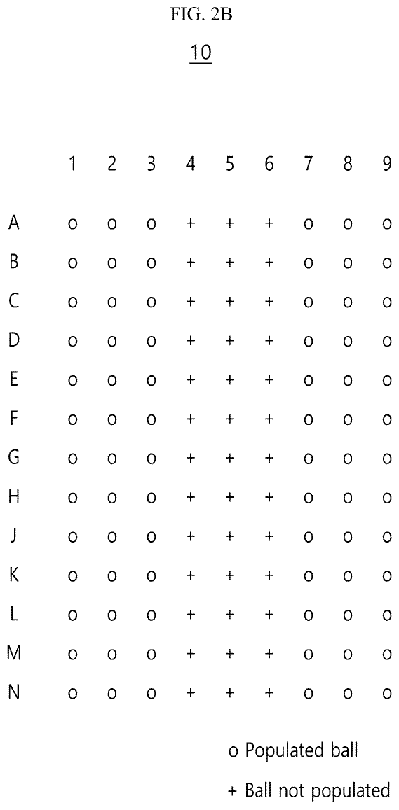

FIGS. 2A and 2B illustrate example arrangements of pins of a memory device according to embodiments of the disclosure.

FIGS. 2A and 2B show an example of the arrangement of pins of a memory device 10. Referring to FIGS. 2A and 2B, the memory device 10 may include pins arranged at the matrix with 13 rows A, B, C, D, E, F, G, H, J, K, L, M, and N and 6 columns. In an embodiment, the six (6) columns may be divided into a first column set including first to third columns and a second column set including seventh to ninth columns. Fourth to sixth columns which are not populated may be present between the first column set and the second column set.

The pins may be electrically populated to a power/ground, a command/address, a clock signal, control signals, and data input/output (I/O) signals. For example, a pin MIR at the G row and second column may indicate the mirror function, a pin CS_n at the H row and third column may correspond to a chip select signal, a pin CA2 at the K row and third column may correspond to a CA bit CA2, and a pin CA3 at the K row and seventh row may correspond to a CA bit CA3.

When the MIR pin at the G row and second column is connected to a power supply voltage VDDQ, the memory device 10 may operate in the mirrored mode; when the MIR pin at the G row and second column is connected to a ground voltage VSS, the memory device 10 may operate in the standard mode.

However, as described above, each of the memory devices 101a, 102a, . . . , etc., 101b, 102b, . . . , etc. according to embodiments of the disclosure may implement the mirror function even though there is no separate pin for the mirror function. Accordingly, when the memory device 10 is implemented according to embodiments of the disclosure, the MIR pin is not necessary any more. In this case, an existing MIR pin may be utilized for any other purpose. For example, the integrity of signal may be improved by populating an I/O signal, a power signal, or a ground signal to the pin at the G row and second column. However, the disclosure is not limited thereto.

In some embodiments, CA pins 11 corresponding to CA bits may have a structure in which even-numbered CA pins CA0, CA2, CA4, CA6, CA8, CA10, and CA12 are physically symmetric to odd-numbered CA pins CA1, CA3, CA5, CA7, CA9, CA11, and CA13. An embodiment of the disclosure may also include the above structure. However, the disclosure is not limited thereto.

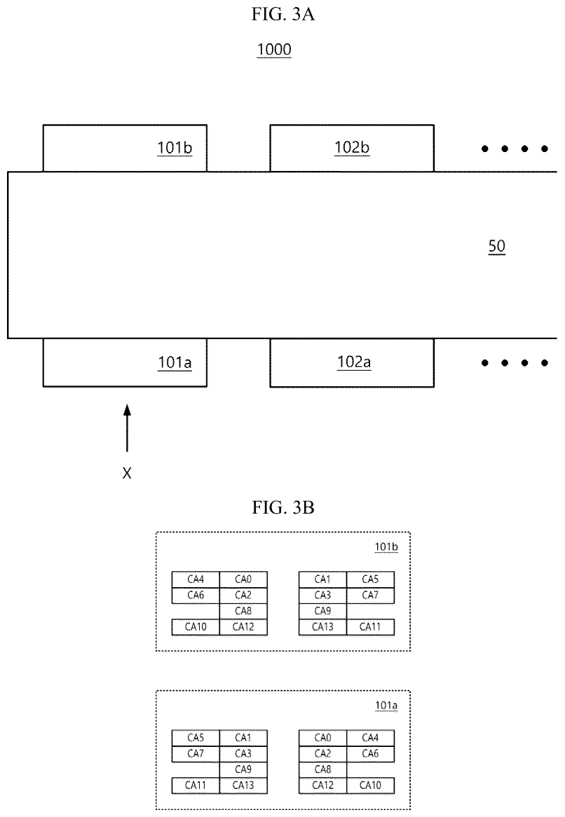

FIGS. 3A and 3B illustrate location relationships of CA pins of memory devices facing away from each other, according to an embodiment of the disclosure. FIG. 3A illustrates a vertical cross-sectional view of the memory module 1000 according to an embodiment of the disclosure. FIG. 3B illustrates a location relationship of CA pins of the first memory device 101a and the second memory device 101b facing away from each other.

For example, referring to FIGS. 3A and 3B, when viewing the first memory device 101a and the second memory device 101b along the X direction, the second memory device 101b may have the arrangement of balls as shown at the top of FIG. 3B, and the first memory device 101a may have the arrangement of balls as shown at the bottom of FIG. 3B.

In some embodiments, because the first memory device 101a and the second memory device 101b have the same pin arrangement and are mounted on the circuit board 50 to face away from each other, when viewing the first memory device 101a and the second memory device 101b along the X direction, the CA pins of the first memory device 101a and the CA pins of the second memory device 101b may have a left-and-right flipped location relationship. For example, referring to FIG. 3B, the even-numbered CA pins CA0, CA2, CA4, CA6, CA8, CA10, and CA12 of the second memory device 101b may respectively face the odd-numbered CA pins CA1, CA3, CA5, CA7, CA9, CA11, and CA13 of the first memory device 101a; the odd-numbered CA pins CA1, CA3, CA5, CA7, CA9, CA11, and CA13 of the second memory device 101b may respectively face the even-numbered CA pins CA0, CA2, CA4, CA6, CA8, CA10, and CA12 of the first memory device 101a.

In this case, according to an embodiment, CA pins facing each other may be electrically connected to each other through a via formed in the circuit board 50. That is, the even-numbered CA pins CA0, CA2, CA4, CA6, CA8, CA10, and CA12 of the second memory device 101b may respectively be connected to the odd-numbered CA pins CA1, CA3, CA5, CA7, CA9, CA11, and CA13 of the first memory device 101a; the odd-numbered CA pins CA1, CA3, CA5, CA7, CA9, CA11, and CA13 of the second memory device 101b may be respectively connected to the even-numbered CA pins CA0, CA2, CA4, CA6, CA8, CA10, and CA12 of the first memory device 101a.

In this case, CA signals applied in common through the circuit board 50 may be applied to the memory devices (the first memory device 101a and the second memory device 101b) through different CA pins of the two memory devices (the first memory device 101a and the second memory device 101b) facing away from each other. Accordingly, one of the two memory devices (the first memory device 101a and the second memory device 101b) (facing away from each other) may operate in the mirrored mode such that the two memory devices (the first memory device 101a and the second memory device 101b) facing away from each other operate identically depending on the CA signals applied in common through the circuit board 50.

For example, the first memory device 101a may operate in the mirrored mode and the second memory device 101b may operate in the standard mode. In this case, when the CA0 to CA13 signals are applied in common through the circuit board 50, the second memory device 101b may use the CA0 to CA13 signals applied to the CA0 to CA13 pins without modification. In some embodiments, the first memory device 101a may internally convert and use CA signals applied to the CA1, CA3, CA5, CA7, CA9, CA11, and CA13 pins into the CA0, CA2, CA4, CA6, CA8, CA10, and CA12 signals and may internally convert and use CA signals applied to the CA0, CA2, CA4, CA6, CA8, CA10, and CA12 pins into the CA1, CA3, CA5, CA7, CA9, CA11, and CA13 signals. Accordingly, the first memory device 101a and the second memory device 101b may operate identically depending on the CA signals applied in common through the circuit board 50.

The first memory device 101a and the second memory device 101b facing away from each other are described above as an example, but the above description will be identically applied to the remaining first memory devices 102a, . . . , etc. and the remaining second memory devices 102b, . . . , etc. facing away from each other.

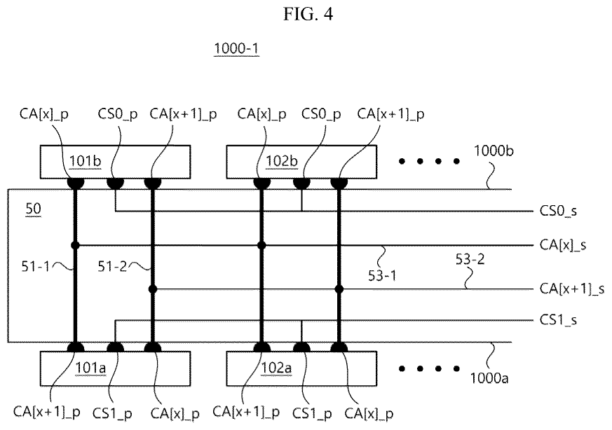

FIG. 4 illustrates a vertical cross-sectional view of a memory module according to an embodiment of the disclosure. A memory module 1000-1 of FIG. 4 may be an embodiment of the memory module 1000 illustrated in FIGS. 1A, 1B, and 3A, but the disclosure is not limited thereto.

According to an embodiment, each of the first memory device 101a and the second memory device 101b may include a plurality of CA pins respectively corresponding to a plurality of CA bits. For example, when the plurality of CA bits includes 14 bits CA0 to CA13, each of the first memory device 101a and the second memory device 101b may include 14 CA pins CA0 to CA13. However, the disclosure is not limited thereto.

The plurality of CA pins may be expressed in FIG. 4 through two CA pins CA [x]_p and CA [x+1]_p. Referring to FIG. 4, each of the first memory device 101a and the second memory device 101b may include the first CA pin CA [x]_p corresponding to a first CA bit CA [x] and the second CA pin CA [x+1]_p corresponding to a second CA bit CA [x+1]. In this case, “x” may have values of 0, 2, 4, 6, 8, 10, and 12.

According to an embodiment, the first CA pin CA [x]_p of the second memory device 101b may be connected to the second CA pin CA [x+1]_p of the first memory device 101a through a first via 51-1 of the circuit board 50, and the second CA pin CA [x+1]_p of the second memory device 101b may be connected to the first CA pin CA [x]_p of the first memory device 101a through a second via 51-2 of the circuit board 50.

In an embodiment, the first and second vias 51-1 and 51-2 may be through vias penetrating the opposite surfaces of the circuit board 50. In this case, the length between the CA pin of the first memory device 101a and the CA pin of the second memory device 101b connected to each other through the vias 51-1 and 51-2 may be minimized. This may mean that the stub is reduced. Accordingly, the signal integrity of CA signals may be improved.

In some embodiments, the circuit board 50 may include a plurality of CA signal lines respectively corresponding to the plurality of CA bits. A plurality of CA signals may be applied to the first memory device 101a and the second memory device 101b through the plurality of signal lines. Each CA signal may include a value of the corresponding CA bit. For example, when the plurality of CA bits constituting the command include 14 bits from CA0 to CA13, the CA0 signal including a value of the CA0 bit may be applied to the first memory device 101a and the second memory device 101b through the CA0 signal line. Also, the CA1 signal including a value of the CA1 bit may be applied to the first memory device 101a and the second memory device 101b through the CA1 signal line. The above description will also be applied to the remaining CA signals.

The plurality of signal lines may be expressed in FIG. 4 through two CA signal lines 53-1 and 53-2. Referring to FIG. 4, the circuit board 50 may include the first signal line 53-1 to which a first CA signal CA [x]_s including a value of the first CA bit CA [x] is applied, and the second signal line 53-2 to which a second CA signal CA [x+1]_s including a value of the second CA bit CA [x+1] is applied.

In this case, according to an embodiment, the first signal line 53-1 may be connected to the first via 51-1, and the second signal line 53-2 may be connected to the second via 51-2.

As such, the first CA signal CA [x]_s may be applied to the first CA pin CA [x]_p of the second memory device 101b and the second CA pin CA [x+1]_p of the first memory device 101a, respectively, through the first signal line 53-1 and the first via 51-1. Also, the second CA signal CA [x+1]_s may be applied to the second CA pin CA [x+1]_p of the second memory device 101b and the first CA pin CA [x]_p of the first memory device 101a, respectively, through the second signal line 53-2 and the second via 51-2.

That is, the second memory device 101b may receive the value of the first CA bit CA [x] through the first CA pin CA [x]_p and may receive the value of the second CA bit CA [x+1] through the second CA pin CA [x+1]_p. In contrast, the first memory device 101a may receive the value of the second CA bit CA [x+1] through the first CA pin CA [x]_p and may receive the value of the first CA bit CA [x] through the second CA pin CA [x+1]_p.

In this case, for the first memory device 101a and the second memory device 101b to operate identically depending on CA signals applied in common, the second memory device 101b may operate in the standard mode, and the first memory device 101a may operate in the mirrored mode. That is, FIG. 4 may correspond to the first embodiment described above.

However, as described above, because the default value set in the mirror information storage regions 101a_1 and 101b_1 of the first memory device 101a and the second memory device 101b corresponds to the standard mode, in an initial state of the memory module 1000-1, all the first memory device 101a and the second memory device 101b operate in the standard mode. Accordingly, it may be necessary to set the second value corresponding to the mirrored mode in the mirror information storage region 101a_1 of the first memory device 101a such that the first memory device 101a operates in the mirrored mode.

To this end, the first memory device 101a may set the second value in the mirror information storage region 101a_1, based on the first command. The first command may include a plurality of CA signals and may be applied from the external memory controller 800 to the CA signal lines 53-1 and 53-2.

According to an embodiment, the first command may be a command in which at least some of values of a plurality of CA bits included in the second command are swapped. For example, the second command may be a command that, when received by a memory device operating in the standard mode, causes the second value to be set in a mirror information storage region of the corresponding memory device.

In some embodiments, the second memory device 101b may receive the value of the first CA bit CA [x] through the first CA pin CA [x]_p and may receive the value of the second CA bit CA [x+1] through the second CA pin CA [x+1]_p. Accordingly, when the second command is applied to the CA signal lines 53-1 and 53-2, the second memory device 101b may receive the second command without modification. In this case, the second memory device 101b operating in the standard mode may set the second value in the mirror information storage region 101b_1, based on the received second command. Of course, according to the first embodiment, because the second memory device 101b may operate in the standard mode, the second command need not be applied actually to the second memory device 101b. As an example, a memory device to which the second command is to be applied may be selected by using the chip select signal.

In contrast, the first memory device 101a may receive the value of the second CA bit CA [x+1] through the first CA pin CA [x]_p and may receive the value of the first CA bit CA [x] through the second CA pin CA [x+1]_p. Accordingly, when the second command is applied to the CA signal lines 53-1 and 53-2, the first memory device 101a may be incapable of receiving the second command without modification. In this case, the first memory device 101a operating in the standard mode may be incapable of setting the second value in the mirror information storage region 101a_1, based on the second command applied to the CA signal lines 53-1 and 53-2.

Accordingly, according to an embodiment of the disclosure, to set the second value in the mirror information storage region 101a_1 of the first memory device 101a, the first command may be applied to the CA signal lines 53-1 and 53-2. In this case, the first command may be a command in which values of the first CA bit CA [x] and the second CA bit CA [x+1] of the second command are swapped. In this case, the first CA bit CA [x] of the first command may have the same value as the second CA bit CA [x+1] of the second command, and the second CA bit CA [x+1] of the first command may have the same value as the first CA bit CA [x] of the second command. That is, when the second command is applied to the CA signal lines 53-1 and 53-2, the first memory device 101a may be capable of receiving the second command. Accordingly, the first memory device 101a operating in the standard mode may be capable of setting the second value in the mirror information storage region 101a_1, based on the first command applied to the CA signal lines 53-1 and 53-2.

In some embodiments, because the first memory device 101a and the second memory device 101b are electrically connected to each other through the vias 51-1 and 51-2, the first command may be applied to the second memory device 101b as well as the first memory device 101a. In this case, because the first command is a command for setting the second value in the mirror information storage regions 101a_1, 102a_1, . . . , etc. of the first memory devices 101a, 102a, . . . , etc., the first command applied to the second memory device 101b may be ignored.

To this end, the chip select signal may be used. Referring to FIG. 4, the first memory device 101a may include a chip select pin CS1_p to which a first chip select signal CS1_s is applied, and the second memory device 101b may include a chip select pin CS0_p to which a second chip select signal CS0_s is applied. Each of the first memory device 101a and the second memory device 101b may effectively receive or ignore the applied CA signals depending on a value of the chip select signal applied to the corresponding chip select pin.

For example, when the chip select signal applied to the corresponding chip select pin has a low value, each of the first memory device 101a and the second memory device 101b may effectively receive the applied CA signals. Also, when the chip select signal applied to the corresponding chip select pin has a high value, each of the first memory device 101a and the second memory device 101b may ignore the applied CA signals.

In this case, while the first command is applied to the CA signal lines 53-1 and 53-2, the first chip select signal CS1_s may have the low value, and the second chip select signal CS0_s may have the high value. Accordingly, the first command may be effectively applied only to the first memory device 101a.

In some embodiments, when the second value is set in the mirror information storage region 101a_1, based on the first command, the first memory device 101a may operate in the mirrored mode. In this case, because the second memory device 101b maintains the standard mode, the first memory device 101a and the second memory device 101b may operate identically depending on the CA signals applied in common.

For example, after the second value is set in the mirror information storage region 101a_1, a new command, for example, a third command may be applied to the CA signal lines 53-1 and 53-2. In this case, the second memory device 101b may receive the third command without modification. Accordingly, the second memory device 101b operating in the standard mode may perform an operation corresponding to the third command while maintaining values of the CA bits included in the third command without modification. In some embodiments, when the third command is applied to the CA signal lines 53-1 and 53-2, the first memory device 101a may receive a fourth command in which at least some of the CA bits included in the third command are swapped. However, because the first memory device 101a is operating in the mirrored mode, the first memory device 101a may perform an operation corresponding to the third command by swapping at least some of values of the CA bits included in the fourth command thus received.

The first memory device 101a and the second memory device 101b are described above as an example. The disclosure is not limited thereto. The application of the above description is not limited to the first memory device 101a and the second memory device 101b. Referring to FIG. 4, the first memory device 102a and the second memory device 102b may also have the same structure and wiring as the first memory device 101a and the second memory device 101b. This may also be applied to the remaining first memory devices and the remaining second memory devices facing away from each other, which are present in the memory module 1000-1 but are not illustrated. Accordingly, the remaining first memory devices 102a, . . . , etc. may also operate the same as the first memory device 101a, and the remaining second memory devices 102b, . . . , etc. may also operate the same as the second memory device 101b.

According to an embodiment, the operation of setting the second value in the mirror information storage regions 101a_1, 102a_1, . . . , etc. of the first memory devices 101a, 102a, . . . , etc. may be performed at an initial step of the module post package repair process for the memory module 1000, but the disclosure is not limited thereto.

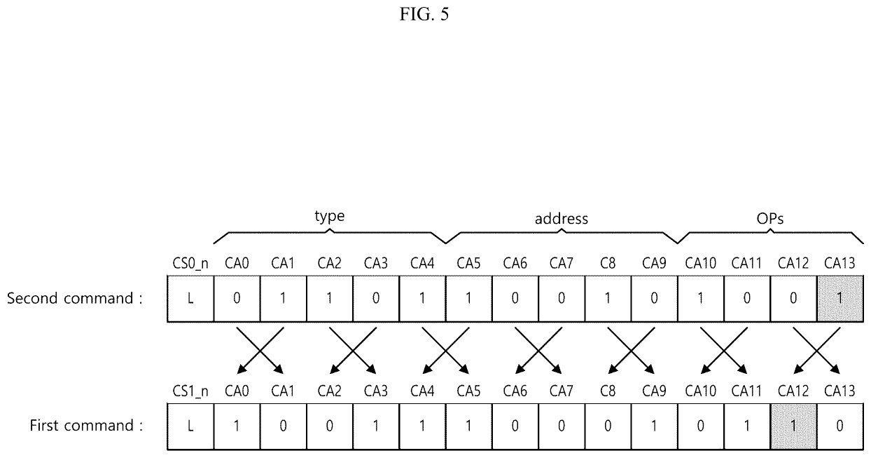

FIG. 5 illustrates a first command according to an embodiment of the disclosure. According to an embodiment, a command may include 14 CA bits from CA0 to CA13. In this case, an operation which is to be performed depending on the command may be determined based on a command truth table which defines the meaning of the CA bits.

For example, a command for setting a value (e.g., the second value) corresponding to the mirrored mode in the mirror information storage regions 101a_1, 102a_1, . . . , etc., 101b_1, 102b_1, . . . , etc. may be defined like the second command illustrated in FIG. 5. Herein, the CA0 to CA4 bits may indicate a kind of an operation, the CA5 to CA9 bits may indicate an address, and the CA13 may indicate a value to be set in the mirror information storage regions 101a_1, 102a_1, . . . , etc., 101b_1, 102b_1, . . . , etc.

That is, according to the second command, a value of “1” corresponding to the mirrored mode may be set in the mirror information storage regions 101a_1, 102a_1, . . . , etc., 101b_1, 102b_1, . . . , etc. having an address of “10010”. In the above embodiment, the default value corresponding to the standard mode may be “0”.

Referring to FIGS. 4 and 5 together, each of the second memory devices 101b, 102b, . . . , etc. may receive a value of the first CA bit CA [x] through the first CA pin CA [x]_p and may receive a value of the second CA bit CA [x+1] through the second CA pin CA [x+1]_p. Accordingly, the second command of “01101100101001” is applied to the CA signal lines 53-1 and 53-2, the second memory devices 101b, 102b, . . . , etc. operating in the standard mode may receive the second command of “01101100101001” without modification, and thus, the value of “1” corresponding to the mirrored mode may be set in the mirror information storage regions 101b_1, 102b_1, . . . , etc.

However, each of the first memory devices 101a, 102a, . . . , etc. may receive a value of the second CA bit CA [x+1] through the first CA pin CA [x]_p and may receive a value of the first CA bit CA [x] through the second CA pin CA [x+1]_p. Accordingly, the second command of “01101100101001” is applied to the CA signal lines 53-1 and 53-2, the first memory devices 101a, 102a, . . . , etc. operating in the standard mode may receive a wrong command of “10011100010110” different from the second command of “01101100101001”, and the value of “1” corresponding to the mirrored mode is incapable of being set in the mirror information storage regions 101a_1, 102a_1, . . . , etc.

Accordingly, according to an embodiment of the disclosure, a command in which at least some of values of the plurality of CA bits included in the second command are swapped, that is, the first command may be applied to the first memory devices 101a, 102a, . . . etc.

For example, referring to FIG. 5, the first command may be a command in which there are swapped a value of the even-numbered CA bit CA0/CA2/CA4/CA6/CA8/CA10/CA12 of the second command and a value of the odd-numbered CA bit CA1/CA3/CA5/CA7/CA9/CA11/CA13 which is next to the even-numbered CA bit CA0/CA2/CA4/CA6/CA8/CA10/CA12 and higher than the even-numbered CA bit CA0/CA2/CA4/CA6/CA8/CA10/CA12. In some embodiments, the first command of “10011100010110” may be implemented through the following swapping of values of the CA bits of the second command: a value (0) of the CA0 bit and a value (1) of the CA1 bit are swapped, a value (1) of the CA2 bit and a value (0) of the CA3 bit are swapped, a value (1) of the CA4 bit and a value (1) of the CA5 bit are swapped, a value (0) of the CA6 bit and a value (0) of the CA7 bit are swapped, a value (1) of the CA8 bit and a value (0) of the CA9 bit are swapped, a value (1) of the CA10 bit and a value (0) of the CA11 bit are swapped, and a value (0) of the CA12 bit and a value (1) of the CA13 bit are swapped.

In this case, when the first command of “10011100010110” is applied to the CA signal lines 53-1 and 53-2, the first memory devices 101a, 102a, . . . , etc. may receive the same values as the CA0 to CA13 bits of the second command, that is, “01101100101001”, and thus, in the first memory devices 101a, 102a, . . . , etc. operating in the standard mode, the value of “1” corresponding to the mirrored mode may be set in the mirror information storage regions 101a_1, 102a_1, . . . , etc.

According to an embodiment, the first command may include a chip select bit CS1_n. In this case, the chip select bit CS1_n may have the low value. This may mean that the first command is effectively applied to the first memory devices 101a, 102a, . . . , etc. While the first command is applied to the first memory devices 101a, 102a, . . . , etc., the high value may be applied to the chip select pins of the second memory devices 101b, 102b, . . . , etc. Accordingly, the first command applied to the second memory devices 101b, 102b, . . . , etc. may be ignored.

In some embodiments, the case where the first and second commands are a “1-cycle command” is illustrated in FIG. 5 as an example, but the disclosure is not limited thereto. According to an embodiment, the first and second commands may be implemented by using a 2-cycle command or a command with three or more cycles. For example, the first and second commands may be implemented by using a mode register write (MRW) command, but the disclosure is not limited thereto.

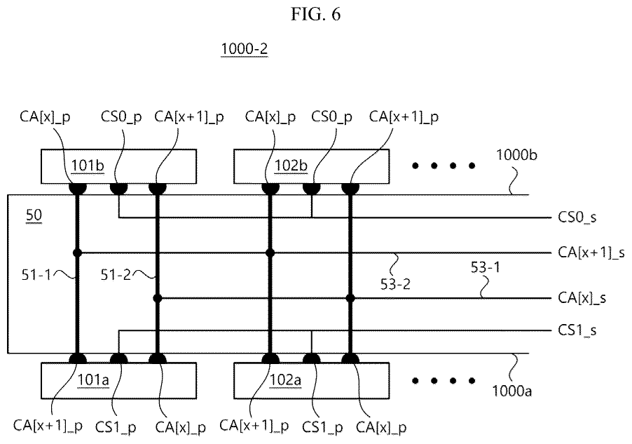

FIG. 6 illustrates a vertical cross-sectional view of a memory module according to an embodiment of the disclosure. A memory module 1000-2 of FIG. 6 may be an embodiment of the memory module 1000 illustrated in FIGS. 1A, 1B, and 3A, but the disclosure is not limited thereto.

The memory module 1000-2 of FIG. 6 may be the same as the memory module 1000-1 of FIG. 4 except that the first signal line 53-1 to which the first CA signal CA [x]_s is applied is connected to the second via 51-2 and the second signal line 53-2 to which the second CA signal CA [x+1]_s is applied is connected to the first via 51-1. Accordingly, the description described with reference to FIGS. 4 and 5 may be identically applied to the memory module 1000-2 of FIG. 6 except for the description associated with the above difference. Below, the difference is described.

Referring to FIG. 6, the first CA signal CA [x]_s may be applied to the second CA pin CA [x+1]_p of the second memory device 101b and the first CA pin CA [x]_p of the first memory device 101a, respectively, through the first signal line 53-1 and the second via 51-2. Also, the second CA signal CA [x+1]_s may be applied to the first CA pin CA [x]_p of the second memory device 101b and the second CA pin CA [x+1]_p of the first memory device 101a, respectively, through the second signal line 53-2 and the first via 51-1.

That is, the first memory device 101a may receive a value of the first CA bit CA [x] through the first CA pin CA [x]_p and may receive a value of the second CA bit CA [x+1] through the second CA pin CA [x+1]_p. In contrast, the second memory device 101b may receive a value of the second CA bit CA [x+1] through the first CA pin CA [x]_p and may receive a value of the first CA bit CA [x] through the second CA pin CA [x+1]_p.

In this case, for the first memory device 101a and the second memory device 101b to operate identically depending on CA signals applied in common, the first memory device 101a may operate in the standard mode, and the second memory device 101b may operate in the mirrored mode. That is, FIG. 6 may correspond to the second embodiment described above.

In this case, to set the second value corresponding to the mirrored mode in the mirror information storage region 101b_1 of the second memory device 101b operating in the standard mode based on the default value, the first command described above may be applied to the CA signal lines 53-1 and 53-2, and the second memory device 101b may receive the second command. That is, as the second value is set in the mirror information storage region 101b_1, the second memory device 101b may operate in the mirrored mode. In some embodiments, because the first memory device 101a maintains the standard mode based on the default value, the first memory device 101a and the second memory device 101b may operate identically depending on the CA signals applied in common.

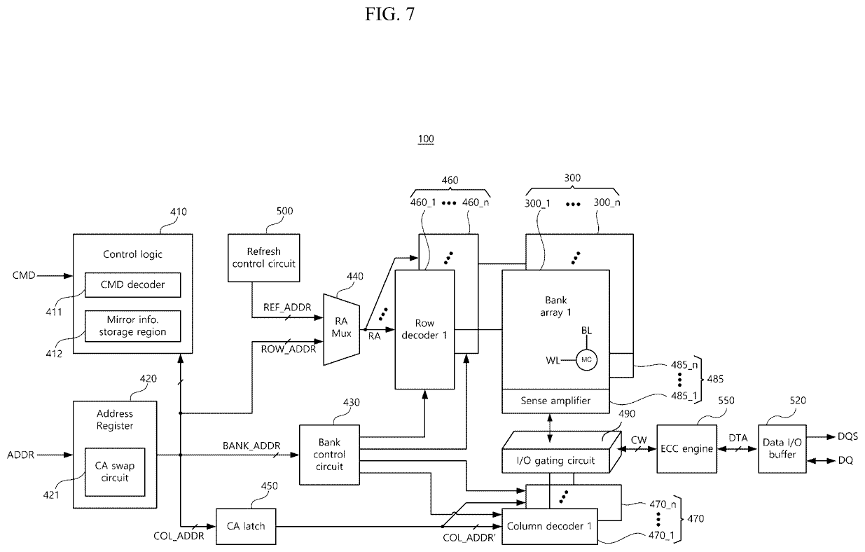

FIG. 7 illustrates a memory device according to an embodiment of the disclosure. A memory device 100 of FIG. 7 may correspond to one of the above memory devices 101a, 102a, . . . , etc., 101b, 102b, . . . , etc., but the disclosure is not limited thereto.

Referring to FIG. 7, the memory device 100 may include control logic 410, an address register 420, bank control circuit 430, a row address multiplexer 440, a column address latch 450, a row decoder 460, a column decoder 470, a memory cell array 300, a sense amplifier unit 485, an input/output gating circuit 490, a data input/output buffer 520, an ECC engine 550, and a refresh control circuit 500.

The control logic 410 may control operations of the memory device 100. For example, the control logic 410 may generate control signals such that the memory device 100 performs the write operation or the read operation.

The control logic 410 may include a command decoder 411 which decodes a command CMD. For example, the command decoder 411 may decode a write enable signal, a row address strobe signal, a column address strobe signal, a chip select signal, etc. and may generate control signals corresponding to the command CMD.

The control logic 410 may include a mirror information storage region 412 which stores a value associated with the mirror function. The mirror information storage region 412 may include a mode register and a nonvolatile memory region. The mirror information storage region 412 may correspond to the above mirror information storage regions 101a_1, 102a_1, . . . , etc., 101b_1, 102b_1, . . . , etc., but the disclosure is not limited thereto. An example in which the mirror information storage region 412 is included in the control logic 410 is illustrated in FIG. 7, but the disclosure is not limited thereto. For example, the mirror information storage region 412 may be placed outside the control logic 410.

The memory cell array 300 may include a plurality of bank arrays 300_1 to 300_n. Each of the bank arrays 300_1 to 300_n may include a word line WL, a bit line BL, and a memory cell MC formed at the intersection of the word line WL and the bit line BL.

The row decoder 460 may include row decoders 460_1 to 460_n respectively connected to the bank arrays 300_1 to 300_n, the column decoder 470 may include column decoders 470_1 to 470_n respectively connected to the bank arrays 300_1 to 300_n, and the sense amplifier unit 485 may include sense amplifiers 485_1 to 485_n respectively connected to the bank arrays 300_1 to 300_n.

The bank arrays 300_1 to 300_n, the row decoders 460_1 to 460_n, the column decoders 470_1 to 470_n, and the sense amplifiers 485_1 to 485_n may constitute first to n-th banks.

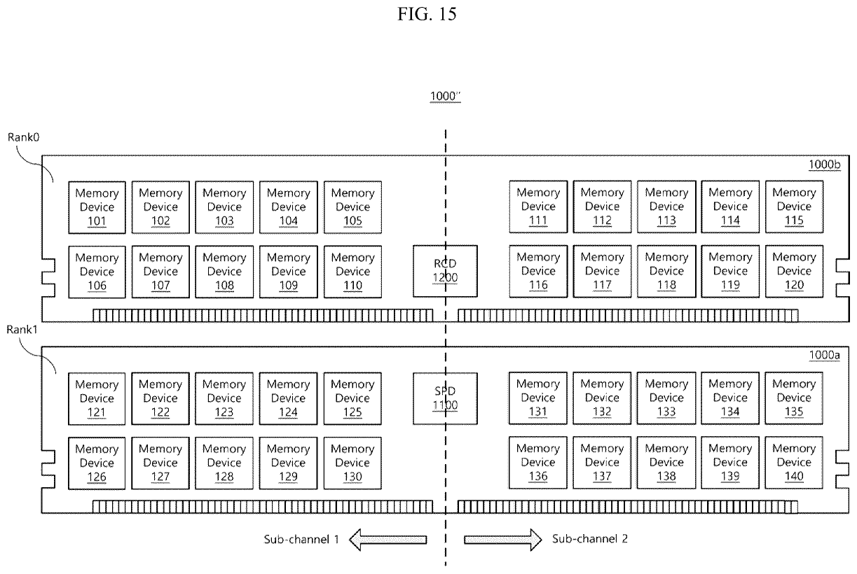

The address register 420 may receive an address ADDR including a bank address BANK_ADDR, a row address ROW_ADDR, and a column address COL_ADDR from the memory controller 800 or a register clock driver (RCD) 1200 (refer to FIG. 15). The address register 420 may provide the received bank address BANK_ADDR to the bank control circuit 430, may provide the received row address ROW_ADDR to the row address multiplexer 440, and may provide the received column address COL_ADDR to the column address latch 450.

The address register 420 may include a command/address swap circuit 421. The command/address swap circuit 421 may swap at least some of values of the CA bits included in the received address ADDR, based on the value set in the mirror information storage region 412.

For example, when the default value (e.g., “0”) corresponding to the standard mode is set in the mirror information storage region 412, the command/address swap circuit 421 may operate in the standard mode. In this case, the command/address swap circuit 421 may maintain and output the received address ADDR without modification. Also, when the second value (e.g., “1”) corresponding to the mirrored mode is set in the mirror information storage region 412, the command/address swap circuit 421 may operate in the mirrored mode. In this case, the command/address swap circuit 421 may swap and output at least some of the values of the CA bits included in the received address ADDR.

According to an embodiment, the command/address swap circuit 421 may operate in the standard mode or the mirrored mode, based on the value set in the mode register of the mirror information storage region 412. Alternatively, according to an embodiment, the command/address swap circuit 421 may operate in the standard mode or the mirrored mode, based on the value set in the nonvolatile memory region of the mirror information storage region 412.

An example in which the command/address swap circuit 421 is included in the address register 420 is illustrated in FIG. 7, but the disclosure is not limited thereto. For example, the command/address swap circuit 421 may be placed outside the address register 420.

The bank control circuit 430 may generate bank control signals in response to the bank address BANK_ADDR. A row decoder corresponding to the bank address BANK_ADDR from among the row decoders 460_1 to 460_n and a column decoder corresponding to the bank address BANK_ADDR from among the column decoders 470_1 to 470_n may be activated in response to the bank control signals.

The row address multiplexer 440 may receive the row address ROW_ADDR from the address register 420 and may receive a refresh row address REF_ADDR from the refresh control circuit 500. The row address multiplexer 440 may selectively output the row address ROW_ADDR or the refresh row address REF_ADDR as a row address RA. The row address RA output from the row address multiplexer 440 may be applied to each of the row decoders 460_1 to 460_n.

A row decoder activated by the bank control circuit 430 from among the row decoders 460_1 to 460_n may decode the row address RA output from the row address multiplexer 440 and may activate a word line corresponding to the row address RA.

The column address latch 450 may receive the column address COL_ADDR from the address register 420 and may temporarily store the received column address COL_ADDR. Also, in a burst mode, the column address latch 450 may gradually (or sequentially) increase the received column address COL_ADDR. The column address latch 450 may apply the temporarily stored column address COL_ADDR or the sequentially increased column address COL_ADDR to each of the column decoders 470_1 to 470_n.

A column decoder activated by the bank control circuit 430 from among the column decoders 470_1 to 470_n may activate a sense amplifier corresponding to the bank address BANK_ADDR and the column address COL_ADDR through the input/output gating circuit 490.

The input/output gating circuit 490 may include the following together with circuits gating input/output data: input data mask logic, read data latches for storing data output from the plurality of bank arrays 300_1 to 300_n, and write drivers for writing data in the plurality of bank arrays 300_1 to 300_n.

Data read from one memory bank array among the plurality of bank arrays 300_1 to 300_n may be sensed by a sense amplifier corresponding to the one memory bank array and may be latched by the read data latches.

The data stored in the read data latches may be provided to the memory controller 800 through the data input/output buffer 520 after ECC decoding for the stored data is performed by the ECC engine 550. Data to be written in one bank array among the plurality of bank arrays 300_1 to 300_n may be provided from the memory controller 800 to the data input/output buffer 520.

Data DQ provided to the data input/output buffer 520 may be provided to the input/output gating circuit 490 after ECC encoding for the data DQ is performed by the ECC engine 550.

In the write operation of the normal mode, the data input/output buffer 520 may provide the data signal DQ to the ECC engine 550. In the read operation of the normal mode, the data input/output buffer 520 may receive the data signal DQ from the ECC engine 550 and may provide the data signal DQ and a data strobe signal DQS to the memory controller 800.

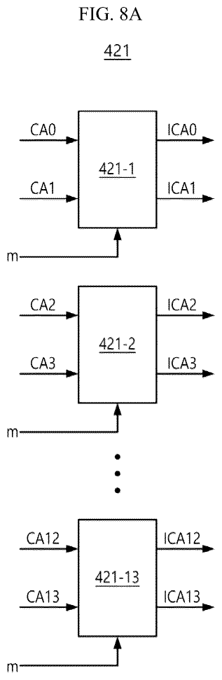

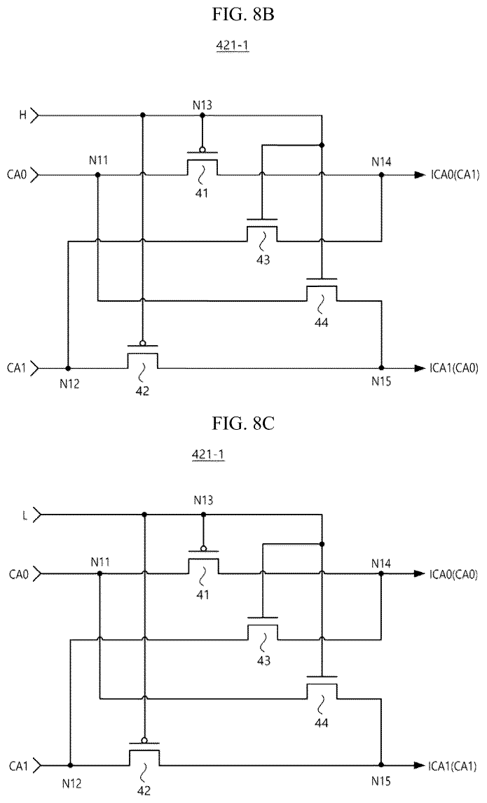

FIG. 8A illustrates the command/address swap circuit 421 according to an embodiment of the disclosure. Referring to FIG. 8A, the command/address swap circuit 421 may include a plurality of unit command/address swap circuits 421-1 to 421-13.

Each of the plurality of unit command/address swap circuits 421-1 to 421-13 may receive an even-numbered CA bit CA [x] and an odd-numbered CA bit CA [x+1] next to the CA bit CA [x] and higher than the CA bit CA [x] and may maintain or swap values the received CA bits, based on a value “m” set in the mirror information storage region 412. Accordingly, each of the plurality of unit command/address swap circuits 421-1 to 421-13 may output internal CA bits ICA [x] and ICA [x+1]. In this case, “x” may have values of 0, 2, 4, 6, 8, 10, and 12.

For example, when the value “m” set in the mirror information storage region 412 is the default value, the unit command/address swap circuit 421-1 may operate in the standard mode and may output internal CA bits ICA0 and ICA1 while maintaining values of the received CA bits CA0 and CA1.

Also, when the value “m” set in the mirror information storage region 412 is the second value, the unit command/address swap circuit 421-1 may operate in the mirrored mode and may swap the values of the received CA bits CA0 and CA1. Accordingly, the unit command/address swap circuit 421-1 may output the swapped CA bits CA0 and CA1 as the internal CA bits ICA0 and ICA1. The above description may be identically applied to the remaining unit command/address swap circuits 421-2 to 421-13.

FIGS. 8B and 8C illustrate examples of a unit command/address swap circuit of FIG. 8A. The unit command/address swap circuit 421-1 is illustrated in FIGS. 8B and 8C as an example, but the remaining unit command/address swap circuits 421-2 to 421-13 may be substantially the same as the unit command/address swap circuit 421-1.

FIG. 8B shows the operation of the unit command/address swap circuit 421-1 when the value “m” set in the mirror information storage region 412 is at a high level “H”. In this case, the high level “H” may refer to a value corresponding to the mirrored mode.

Referring to FIG. 8B, the unit command/address swap circuit 421-1 may include PMOS transistors 41 and 42 and NMOS transistors 43 and 44.

The PMOS transistor 41 may include a first electrode connected to a first node N11 and receiving a value of bit CA0, a gate electrode connected to a third node N13 and receiving the value “m” set in the mirror information storage region 412, and a second electrode connected to a fourth node N14 and outputting the internal CA bit ICA0. The PMOS transistor 42 may include a first electrode connected to a second node N12 and receiving a value of bit CA1, a gate electrode connected to the third node N13 and receiving the value “m” set in the mirror information storage region 412, and a second electrode connected to a fifth node N15 and outputting the internal address bit ICA1.

The NMOS transistor 43 may include a first electrode connected to the second node N12 and receiving a value of bit CA1, a gate electrode connected to the third node N13 and receiving the value “m” set in the mirror information storage region 412, and a second electrode connected to the fourth node N14. The NMOS transistor 44 may include a first electrode connected to the first node N11 and receiving a value of bit CA0, a gate electrode connected to the third node N13 and receiving the value “m” set in the mirror information storage region 412, and a second electrode connected to the fifth node N15.

When the value “m” set in the mirror information storage region 412 is at the high level “H”, the PMOS transistors 41 and 42 may be turned off, and the NMOS transistors 43 and 44 may be turned on. Accordingly, the unit command/address swap circuit 421-1 may output the value of the CA1 bit as the internal CA bit ICA0 and may output the value of the CA0 bit as the internal CA bit ICA1. That is, in this case, the memory device 100 may operate in the mirrored mode.

FIG. 8C shows the operation of the unit command/address swap circuit 421-1 when the value “m” set in the mirror information storage region 412 is at a low level “L”. In this case, the low level “L” may refer to a value corresponding to the standard mode.

Referring to FIG. 8C, when the value “m” set in the mirror information storage region 412 is at the low level “L”, the PMOS transistors 41 and 42 may be turned on, and the NMOS transistors 43 and 44 may be turned off. Accordingly, the unit command/address swap circuit 421-1 may output the value of the CA0 bit as the internal CA bit ICA0 and may output the value of the CA1 bit as the internal CA bit ICA1. That is, in this case, the memory device 100 may operate in the standard mode.

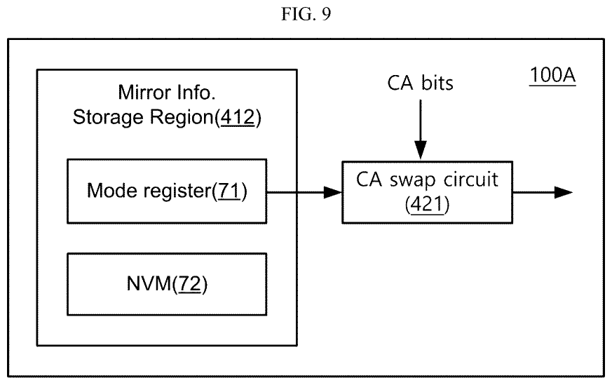

FIG. 9 illustrates a partial configuration of a memory device according to an embodiment of the disclosure. A memory device 100A of FIG. 9 may correspond to one of the above memory devices 101a, 102a, . . . , etc., 101b, 102b, . . . , etc., but the disclosure is not limited thereto.

Referring to FIG. 9, the memory device 100A may include the mirror information storage region 412 and the command/address swap circuit 421.

The command/address swap circuit 421 may swap at least some of values of the applied CA bits, based on a value set in a mode register 71. For example, when the default value corresponding to the standard mode is set in the mode register 71, the command/address swap circuit 421 may maintain the values of the applied CA bits. Accordingly, the memory device 100A may operate in the standard mode. In some embodiments, when the second value corresponding to the mirrored mode is set in the mode register 71, the command/address swap circuit 421 may swap at least some of the values of the applied CA bits. Accordingly, the memory device 100A may operate in the mirrored mode.

The mirror information storage region 412 may store a value associated with the mirror function. The mirror information storage region 412 may include the mode register 71 and a nonvolatile memory region (NVM) 72.

When the memory device 100A is powered up, the nonvolatile memory region 72 may store the value set in the mode register 71. The value stored in the nonvolatile memory region 72 may be maintained even though the power of the memory device 100A is turned off. To this end, for example, the nonvolatile memory region 72 may be implemented with one of an anti-fuse array, a mask read only memory (MROM), and an OTP memory such as an OTP programmable read only memory (PROM). However, this is provided as an example.

According to an embodiment, the nonvolatile memory region 72 may be implemented with one of a multi-time programmable (multi-time program (MTP) voltage) memory, an e-fuse array, a NAND flash memory, a NOR flash memory, a magnetic random access memory (MRAM), a spin torque transfer-MRAM (STT-MRAM), a resistive random access memory (ReRAM), and a phase change random access memory (PRAM).

For example, the default value may be stored in the nonvolatile memory region 72. The default value may be stored in advance in the nonvolatile memory region 72 in the process of manufacturing the memory device 100A. When the memory device 100A is powered up in a state where the default value is stored in the nonvolatile memory region 72, the default value may be set in the mode register 71. In this case, because the command/address swap circuit 421 maintains values of the applied CA bits, the memory device 100A may operate in the standard mode. That is, when the memory module 1000/1000-1/1000-2 is initially powered up, the memory device 100A mounted in the memory module 1000/1000-1/1000-2 may operate in the standard mode.

In some embodiments, assuming the embodiment of FIG. 4, when the memory device 100A is the first memory device 101a/102a/etc., the memory device 100A operating in the standard mode may set the second value corresponding to the mirrored mode in the mode register 71, based on the first command applied to the plurality of CA signal lines. In this case, because the command/address swap circuit 421 swaps at least some of values of the applied CA bits, the memory device 100A may operate in the mirrored mode.

According to an embodiment, the memory device 100A may change the default value stored in the nonvolatile memory region 72 to the second value in response to that the second value is set in the mode register 71. As the second value is stored in the nonvolatile memory region 72 instead of the default value, the second value may be set in the mode register 71 when the memory device 100A is powered up later.

According to an embodiment, the nonvolatile memory region 72 may be implemented with an OTP memory. In this case, an initial state of the OTP memory may correspond to the default value. Accordingly, when the memory device 100A is powered up, the default value may be set in the mode register 71, and the memory device 100A may operate in the standard mode.

Afterwards, when the first command is applied to the plurality of CA signal lines, the memory device 100A operating in the standard mode may set the second value in the mode register 71 and may then operate in the mirrored mode. In response to that the second value is set in the mode register 71, the memory device 100A may perform the program operation on the OTP memory. A state where there is performed the program operation on the OPT memory may correspond to the second value. Accordingly, the second value may be permanently stored in the OTP memory.

According to an embodiment, the operation of storing or programming the second value set in the mode register 71 in the nonvolatile memory region 72 may be performed in a test mode register set (TMRS) mode. The TMRS mode may be a kind of test mode in which a memory module and/or a memory device is tested. According to an embodiment, to enter the test mode, a command for entering the test mode may be provided from the memory controller 800 to the memory device 100A. The memory device 100A which receives the command for entering the test mode may enter the TMRS mode.

According to an embodiment, to prevent the memory device 100A from entering the TMRS mode unintentionally, a safety key (or a guard key) may be received from the memory controller 800. Only when the safety key is correctly received, the memory device 100A may enter the TMRS mode. For example, the safety key may be defined as a setting value of one or more MRW commands determined in advance. According to an embodiment, the safety key may be received together with the command for entering the test mode. Alternatively, according to an embodiment, the safety key may be received after the command for entering the test mode is received.

Afterwards, when the memory device 100A enters the TMRS mode, the memory controller 800 may program the second value set in the mode register 71 of the memory device 100A in the nonvolatile memory region 72. In an embodiment, the operation of programming the second value set in the mode register 71 in the nonvolatile memory region 72 may be called an OTP program operation.

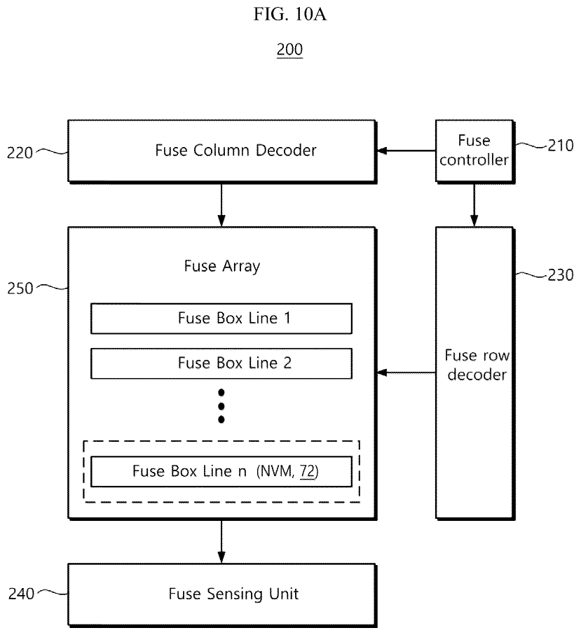

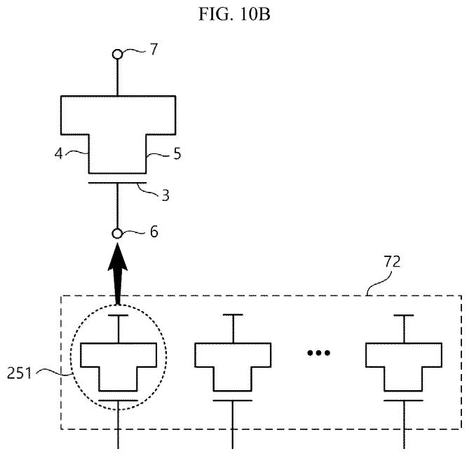

FIGS. 10A and 10B illustrate an example in which a nonvolatile memory region of FIG. 9 is implemented through a fuse array. FIG. 10A shows an example of a fuse circuit 200 including the nonvolatile memory region 72 of FIG. 9. FIG. 10B shows an example in which the nonvolatile memory region 72 is implemented by using anti-fuse cells of a fuse array. Below, the fuse circuit 200 is implemented to be included in the control logic 410.

Referring to FIG. 10A, the fuse circuit 200 may include a fuse controller 210, a fuse column decoder 220, a fuse row decoder 230, a fuse sensing unit 240, and a fuse array 250.

The fuse controller 210 may be electrically connected to the fuse column decoder 220 and the fuse row decoder 230 and may control all the operations of the fuse circuit 200.

The fuse column decoder 220 may select a column of fuse cells in the fuse array 250. The fuse row decoder 230 may select a row of fuse cells in the fuse array 250. The fuse sensing unit 240 may sense whether the fuse cells in the fuse array 250 are programmed.

The fuse array 250 may include a plurality of fuse box lines Fuse Box Line 1 to Fuse Box Line n. Each of the plurality of fuse box lines Fuse Box Line 1 to Fuse Box Line n may include a plurality of fuse cells.

In an embodiment, some of the plurality of fuse box lines Fuse Box Line 1 to Fuse Box Line n may be used for a repair operation. For example, in a post package repair operation, the first fuse box line Fuse Box Line 1 may be used to program one fail address.

In an embodiment, some of the plurality of fuse box lines Fuse Box Line 1 to Fuse Box Line n may be used to store a value associated with the mirror function. That is, some of the plurality of fuse box lines Fuse Box Line 1 to Fuse Box Line n may be used as the nonvolatile memory region 72 of FIG. 9. For example, as illustrated in FIG. 10A, the n-th fuse box line Fuse Box Line n may be designated as a region including the nonvolatile memory region 72. In the OTP program operation, the second value set in the mode register 71 may be programmed in the region corresponding to the nonvolatile memory region 72 from among the n-th fuse box line Fuse Box Line n.

Referring to FIG. 10B, the n-th fuse box line Fuse Box Line n including the nonvolatile memory region 72 may include a plurality of anti-fuses 251. Each of the anti-fuses 251 may have a unique column address and a unique row address. According to an embodiment, at least one of the plurality of anti-fuses 251 may be set to the nonvolatile memory region 72.

The anti-fuse 251 is a resistive element whose electrical characteristic is opposite to that of a fuse element. The anti-fuse 251 may have a high resistance value in an unprogrammed state and may have a low resistance value in a programmed state.

The anti-fuse 251 may be formed, in general, in the shape where a dielectric is interposed between conductors. The program operation on the anti-fuse 251 may be performed by applying a high voltage across the conductors being the opposite ends of the anti-fuse 251 such that the dielectric between the conductors is broken down. As a result of the program operation, the conductors being the opposite ends of the anti-fuse 251 may be short-circuited, and thus, the anti-fuse 251 may have a low resistance value.

For example, the anti-fuse 251 may be implemented with a depletion-type MOS transistor where a source 4 and a drain 5 are connected. In an initial state, because a first node 6 connected to a gate electrode 3 and a second node 7 connected in common to the source 4 and the drain 5 are separated from each other by a gate oxide layer interposed therebetween, a resistance between the first node 6 and the second node 7 is considerably large. This state may be defined as an unprogrammed state.

When a breakdown voltage is applied between the first node 6 and the second node 7, the gate oxide layer of the anti-fuse 251 may be broken down. When the gate oxide layer is broken down, the resistance between the first node 6 and the second node 7 is decreased. This state may be defined as a programmed state.

As described above, according to an embodiment of disclosure, the nonvolatile memory region 72 may be implemented by using an anti-fuse. The second value set in the mode register 71 may be permanently programmed in the nonvolatile memory region 72 by breaking down the gate oxide layer of the anti-fuse in the OTP program operation.

The description is given above as the fuse circuit 200 is included in the control logic 410. However, this is provided as an example, and the fuse circuit 200 may be implemented independently of the control logic 410.

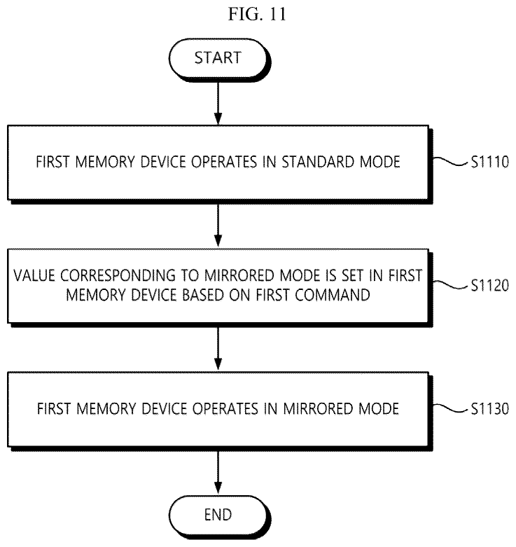

FIG. 11 illustrates an operating method of a memory module according to an embodiment of the disclosure. In FIG. 11, the description which is given above will be omitted or simplified.

Referring to FIG. 11, in operation S1110, the first memory device 101a and the second memory device 101b mounted in the memory module 1000 may operate in the standard mode.

In some embodiments, the first memory device 101a and the second memory device 101b may be mounted on opposite surfaces of the circuit board 50 so as to face away from each other and may respectively include a first mode register and a second mode register. In this case, each of the first memory device 101a and the second memory device 101b may operate in the standard mode or the mirrored mode, based on a value set in the corresponding mode register.

According to an embodiment, the default value corresponding to the standard mode may be set in the first mode register and the second mode register. Accordingly, the first memory device 101a may operate in the standard mode, based on the default value set in the first mode register, and the second memory device 101b may operate in the standard mode, based on the default value set in the second mode register.

In operation S1120, the first memory device 101a may set a value corresponding to the mirrored mode in the first mode register, based on the first command applied to the plurality of signal lines connected to the first memory device 101a. In this case, the first command may be a command in which at least some of values of the plurality of command/address bits included in the second command are swapped. Also, the second command may be a command for setting the value corresponding to the mirrored mode in the second mode register. This is described above, and thus, additional description will be omitted to avoid redundancy.

In operation S1130, the first memory device 101a may operate in the mirrored mode, based on the value corresponding to the mirrored mode set in the first mode register.

That is, the CA pins of the first memory device 101a and the second memory device 101b mounted to face away from each other may be electrically connected to each other through the through vias formed in the circuit board 50. Accordingly, the CA signals may be applied in common to the first memory device 101a and the second memory device 101b.

According to an embodiment, for the first memory device 101a and the second memory device 101b to use the CA signals applied in common together, while the second memory device 101b is operating in the standard mode, the first memory device 101a may operate in the mirrored mode. To this end, the second value corresponding to the mirrored mode may be set in the first mode register of the first memory device 101a.

However, because both the first memory device 101a and the second memory device 101b operate in the standard mode initially, while the first memory device 101a which will operate in the mirrored mode is operating the standard mode, a command of a special format (i.e., the first command) is required to set the second value in the first mode register.

When the first memory device 101a is set to operate in the mirrored mode based on the first command applied to the plurality of signal lines, the first memory device 101a may operate in the mirrored mode, and the second memory device 101b may operate in the standard mode. Accordingly, the first memory device 101a and the second memory device 101b may perform the same operation depending on the CA signals applied in common.

According to an embodiment, after operation S1120, the first memory device 101a may change the default value stored in the nonvolatile memory region 72 to the value which corresponds to the mirrored mode and is set in the first mode register. This is described with reference to FIGS. 9, 10A, and 10C, and thus, additional description will be omitted to avoid redundancy.

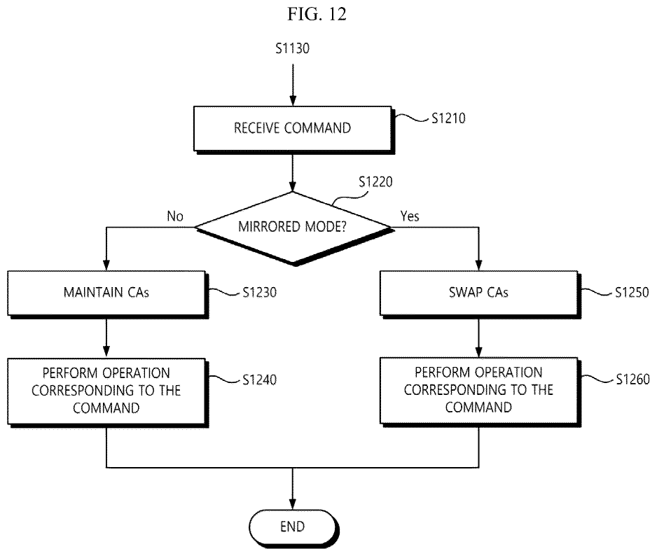

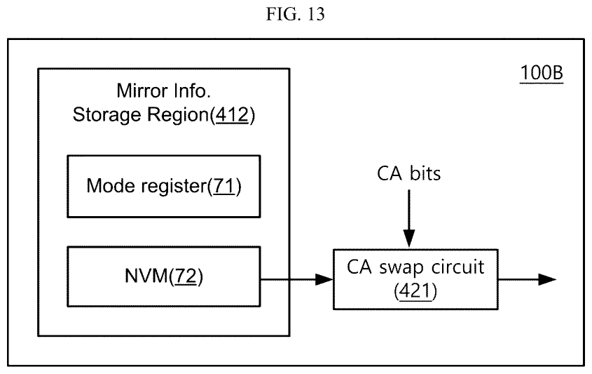

FIG. 12 illustrates an operating method of a memory module according to an embodiment of the disclosure. In FIG. 12, the description which is given above will be omitted or simplified.

Referring to FIG. 12, in operation S1210, the memory module 1000 may receive a command. For example, as operation S1130 is performed, the first memory device 101a may operate in the mirrored mode, and the second memory device 101b may operate in the standard mode. In this state, the third command may be newly input to the memory module 1000.

In operation S1220, each of the first memory device 101a and the second memory device 101b may determine whether to operate in the mirrored mode. For example, each of the first memory device 101a and the second memory device 101b may check the value set in the mirror information storage region (i.e., the mode register 71 and/or the nonvolatile memory region 72) included therein and may determine whether to operate in the mirrored mode.

According to an embodiment, the second memory device 101b may receive the third command without modification. In this case, because the second memory device 101b operates in the standard mode, in operation S1230, the second memory device 101b may maintain values of the plurality of CA bits included in the third command. Accordingly, in operation S1240, the second memory device 101b may perform an operation corresponding to the third command input to the memory module 1000.

According to an embodiment, the first memory device 101a may receive the fourth command in which values of the plurality of CA bits included in the third command are swapped. In this case, because the first memory device 101a operates in the mirrored mode, in operation S1250, the first memory device 101a may swap the values of the plurality of CA bits included in the fourth command thus received. Accordingly, in operation S1260, the first memory device 101a may perform the operation corresponding to the third command thus received.

The first memory device 101a and the second memory device 101b facing away from each other are described with reference to FIGS. 11 and 12 as an example, but the remaining first memory devices 102a, . . . , etc. and the remaining second memory devices 102b, . . . , etc. facing away from each other may also operate in the same manner as described.

FIG. 13 illustrates a partial configuration of a memory device according to an embodiment of the disclosure. A memory device 100B of FIG. 13 may correspond to one of the above memory devices 101a, 102a, . . . , etc., 101b, 102b, . . . , etc., but the disclosure is not limited thereto.

Referring to FIG. 13, the memory device 100B may include the mirror information storage region 412 and the command/address swap circuit 421. The memory device 100B of FIG. 13 is the same as the memory device 100A of FIG. 9 except that the command/address swap circuit 421 operates based on a value set in the nonvolatile memory region 72. Accordingly, as long as it is not contradictory, the description given with reference to FIG. 9 may be identically applied to the memory device 100B of FIG. 13 except for the above difference. Below, the difference is described.

The command/address swap circuit 421 may swap at least some of values of the applied CA bits, based on the value set in the nonvolatile memory region 72. For example, when the default value corresponding to the standard mode is set in the nonvolatile memory region 72, the command/address swap circuit 421 may maintain the values of the applied CA bits. Accordingly, the memory device 100B may operate in the standard mode. In some embodiments, when the second value corresponding to the mirrored mode is set in the nonvolatile memory region 72, the command/address swap circuit 421 may swap at least some of the values of the applied CA bits. Accordingly, the memory device 100B may operate in the mirrored mode. That is, unlike the memory device 100A of FIG. 9, the memory device 100B may operate in the standard mode or the mirrored mode, based on the value set in the nonvolatile memory region 72.

For example, the default value may be stored in the nonvolatile memory region 72. In an embodiment, the default value may be stored in advance in the nonvolatile memory region 72 in the process of manufacturing the memory device 100B. When the memory device 100B is powered up in a state where the default value is stored in the nonvolatile memory region 72, the command/address swap circuit 421 may maintain the values of the applied CA bits, and the memory device 100B may operate in the standard mode. That is, when the memory module 1000/1000-1/1000-2 is initially powered up, the memory device 100B mounted in the memory module 1000/1000-1/1000-2 may operate in the standard mode.

In the embodiment of FIG. 4, when the memory device 100B is the first memory device 101a/102a/etc., the memory device 100B operating in the standard mode may set the second value corresponding to the mirrored mode in the mode register 71, based on the first command applied to the plurality of signal lines.

In this case, because whether the memory device 100B operates in the mirrored mode is determined depending on the value set in the nonvolatile memory region 72, the memory device 100B does not operate in the mirrored mode even though the second value is set in the mode register 71. That is, according to an embodiment of the disclosure, the memory device 100B may operate in the mirrored mode only when the second value is programmed in the nonvolatile memory region 72 depending on the OTP program operation after the second value is set in the mode register 71.

As described with reference to FIG. 9, the OTP program operation process includes a process in which the memory device 100B receives the command for entering the test mode or additional commands such as a safety key. In this case, for the memory device 100B operating in the standard mode to perform the OTP program operation depending on the additional commands, the additional commands may also be input to the memory device 100B in a state where values of the CA bits are swapped like the first command.

Accordingly, according to an embodiment, the memory device 100B may receive commands where the values of the CA bits are swapped, until the second value set in the mode register 71 is programmed in the nonvolatile memory region 72. Accordingly, when the second value is programmed in the nonvolatile memory region 72, the memory device 100B may operate in the mirrored mode. Operations which are performed after the second value is programmed in the nonvolatile memory region 72 are the same as those of the memory device 100A of FIG. 9, and thus, additional description will be omitted to avoid redundancy.

FIG. 14 illustrates a memory system according to an embodiment of the disclosure. Referring to FIG. 14, a memory system 1400 may include a memory module 1000′ and the memory controller 800.

The memory module 1000′ may be an embodiment of the memory module 1000/1000-1/1000-2 illustrated in FIGS. 1A, 1B, 3A, 4, and 6, but the disclosure is not limited thereto. The memory module 1000′ may include the first memory devices 101a, 102a, . . . , etc. and the second memory devices 101b, 102b, . . . , etc., which are mounted on opposite surfaces 1000a and 1000b of a circuit board to face away from each other, a serial presence detect (SPD) 1100, and an RCD 1200.

The first memory devices 101a, 102a, . . . , etc. and the second memory devices 101b, 102b, . . . , etc. may respectively include the corresponding mirror information storage regions 101a_1, 102a_1, . . . , etc., 101b_1, 102b_1, . . . , etc. In this case, each of the mirror information storage regions 101a_1, 102a_1, . . . , etc., 101b_1, 102b_1, . . . , etc. may include the mode register 71 and the nonvolatile memory region 72.

In some embodiments, each of the first memory devices 101a, 102a, . . . , etc. and the second memory devices 101b, 102b, . . . , etc. may operate in the standard mode or the mirrored mode, based on the value set in the corresponding one of the mirror information storage regions 101a_1, 102a_1, . . . , etc., 101b_1, 102b_1, . . . , etc. For example, each of the first memory devices 101a, 102a, . . . , etc. and the second memory devices 101b, 102b, . . . , etc. may operate in the standard mode or the mirrored mode, based on the value set in the corresponding mode register 71. Alternatively, each of the first memory devices 101a, 102a, . . . , etc. and the second memory devices 101b, 102b, . . . , etc. may operate in the standard mode or the mirrored mode, based on the value set in the corresponding nonvolatile memory region 72.

In some embodiments, the default value corresponding to the standard mode may be set in the mirror information storage regions 101a_1, 102a_1, . . . , etc., 101b_1, 102b_1, . . . , etc. For example, the default value may be initially stored in the nonvolatile memory region 72 of each of the mirror information storage regions 101a_1, 102a_1, . . . , etc., 101b_1, 102b_1, . . . , etc. Accordingly, the default value may be set in the mode register 71 of each of the mirror information storage regions 101a_1, 102a_1, . . . , etc., 101b_1, 102b_1, . . . , etc. In this case, each of the first memory devices 101a, 102a, . . . , etc. and the second memory devices 101b, 102b, . . . , etc. may operate in the standard mode.

The SPD 1100 may include various kinds of information about the memory module 1000′. For example, the SPD 1100 may include initial information or device information (DI) of the memory module 1000′. In an embodiment, the SPD 1100 may include the initial information or the device information (DI) of the memory module 1000′, such as a module shape, a module configuration, a storage capacity, a module kind, and an execution environment. The SPD 1100 may be implemented with an electrically erasable programmable read only memory (EEPROM) device, but the disclosure is not limited thereto.

For example, the SPD 1100 may communicate with the memory controller 800 through a serial bus. Also, the SPD 1100 may communicate with the RCD 1200 through a serial bus. In an embodiment, the serial bus may include at least one of 2-line serial buses such as an inter integrated circuit (I2C), a system management bus (SMBus), a power management bus (PMBus), an intelligent platform management interface (IPMI), and a management component transport protocol (MCTP), but the disclosure is not limited thereto.

The RCD 1200 may control the first memory devices 101a, 102a, . . . , etc. and the second memory devices 101b, 102b, . . . , etc. under control of the memory controller 800. For example, the RCD 1200 may receive the address ADDR, the command CMD, and a clock signal CK from the memory controller 800. The RCD 1200 may transfer the received signals to the first memory devices 101a, 102a, . . . , etc. and the second memory devices 101b, 102b, . . . , etc. Accordingly, the first memory devices 101a, 102a, . . . , etc. and the second memory devices 101b, 102b, . . . , etc. may write data received through a data signal DQ and a data strobe signal DQS or may output the stored data through the data signal DQ and the data strobe signal DQS.

The memory controller 800 may control the memory module 1000′. For example, the memory controller 800 may control the memory module 1000′ depending on a request of a processor supporting various applications such as a server application, a personal computer (PC) application, and a mobile application. For example, the memory controller 800 may be included in a host including a processor and may control the memory module 1000′ depending on a request of the processor. According to an embodiment, the memory controller 800 may be included in various external devices such as test equipment testing the memory module 1000′, inspection equipment, and packaging equipment.

To control the memory module 1000′, the memory controller 800 may transmit a command and/or an address to the memory module 1000′. Also, the memory controller 800 may transmit data to the memory module 1000′ or may receive data from the memory module 1000′.

When the memory system 1400 is booted up, the memory controller 800 may receive the initial information and/or the device information (DI) of the memory module 1000′ from the SPD 1100 and may recognize and control the memory module 1000′ based on the received information. For example, the memory controller 800 may identify a type of the first memory devices 101a, 102a, . . . , etc. and the second memory devices 101b, 102b, . . . , etc. included in the memory module 1000′, based on the information received from the SPD 1100.

In particular, according to an embodiment, the memory controller 800 may identify memory devices, which are to be used in the mirrored mode, from among the first memory devices 101a, 102a, . . . , etc. and the second memory devices 101b, 102b, . . . , etc., based on the information received from the SPD 1100.

When the first memory devices 101a, 102a, . . . , etc. are identified as memory devices to be used in the mirrored mode, the memory controller 800 may apply, to the memory module 1000′, the first command for setting the second value corresponding to the mirrored mode in the mode register 71 of the first memory devices 101a, 102a, . . . , etc. In this case, the first command may be a command in which at least some of values of the plurality of CA bits included in the second command are swapped. Herein, when a memory device operating in the standard mode receives the second command, the second command may be a command for setting the second value in a mirror information storage region of the corresponding memory device. For example, the second command may be a command for setting the second value in the mode register 71 of each of the second memory devices 101b, 102b, . . . , etc.

According to an embodiment, the memory controller 800 may apply the first command to the memory module 1000′ during the first operation which is performed after memory devices to be used in the mirrored mode are identified based on the information received from the SPD 1100, but the disclosure is not limited thereto. In some embodiments, the first command(s) may be defined in advance for each kind of the memory module 1000′ and may be stored in advance in the memory controller 800 or a storage device of a host including the memory controller 800, but the disclosure is not limited thereto.

Accordingly, when the first command is applied to the memory module 1000′, the second value corresponding to the mirrored mode may be set in the mode register 71 of each of the first memory devices 101a, 102a, . . . , etc. operating in the standard mode. Afterwards, the first memory devices 101a, 102a, . . . , etc. may be used in the mirrored mode.

FIG. 15 illustrates a configuration of a memory module according to an embodiment of the disclosure. Referring to FIG. 15, a memory module 1000″ may include a plurality of memory devices 101 to 140 disposed on the opposite surfaces, that is, first and second surfaces 1000a and 1000b. Also, the memory module 1000″ may include the SPD 1100 disposed on the center of the first surface 1000a and the RCD 1200 disposed on the center of the second surface 1000b.

The plurality of memory devices 101 to 120 disposed on the second surface 1000b of the memory module 1000″ may be included in a first rank Rank0 and may be disposed to be divided into the left and the right with respect to the RCD 1200. Also, the plurality of memory devices 121 to 140 disposed on the first surface 1000a of the memory module 1000″ may be included in a second rank Rank1 and may be disposed to be divided into the left and the right with respect to the SPD 1100.

Each of the memory devices 101 to 140 may be the memory device 100 of FIG. 7 or the memory device 100A of FIG. 9 and may include the mode register 71 and the nonvolatile memory region 72. The default value corresponding to the standard mode may be stored in the nonvolatile memory region 72 of each of the memory devices 101 to 140. Accordingly, when the memory module 1000″ is powered up, all the memory devices 101 to 140 may operate in the standard mode.

In this case, according to an embodiment, a configuration of the plurality of memory devices 101 to 140 may be similar to that of FIG. 4. That is, the plurality of memory devices 101 to 140 may have a connection relationship in which the memory devices 101 to 120 included in the first rank Rank0 receive values of the CA bits without modification and the memory devices 121 to 140 included in the second rank Rank1 receive the CA bits in a state where the values of the CA bits are swapped.

In this case, the memory devices 121 to 140 included in the second rank Rank1 may be used in the mirrored mode, and the memory controller 800 may identify that the memory devices 121 to 140 to be used in the mirrored mode from among the plurality of memory devices 101 to 140, based on the information stored in the SPD 1100.

Accordingly, the memory controller 800 may apply the first command to the memory module 1000″. For example, the memory controller 800 may provide the first command to the RCD 1200, and the RCD 1200 may apply the first command received from the memory controller 800 to the plurality of signal lines included in the circuit board 50. Accordingly, the memory devices 121 to 140 included in the second rank Rank1 may operate in the mirrored mode.

In this case, according to an embodiment, the memory devices 101 to 110 and 121 to 130 disposed on the left of the memory module 1000″ may communicate with the memory controller 800 through a first sub-channel Sub_Channel 1. Also, the memory devices 111 to 120 and 131 to 140 disposed on the right of the memory module 1000″ may communicate with the memory controller 800 through a second sub-channel Sub_Channel 2. Accordingly, the RCD 1200 may apply the first command simultaneously to the left memory devices 121 to 130 of the second rank Rank1 and the right memory devices 131 to 140 of the second rank Rank1 by using the first and second sub-channels Sub_Channel 1 and Sub_Channel 2 independently of each other.

In some embodiments, the number and arrangement of components (i.e., memory devices 101 to 140, SPDs 1100, and RCDs 1200) included in the memory module 1000″ may be provided as an example and may be variously changed or modified depending on embodiments.

Embodiments in which the first value corresponding to the standard mode is used as the default value are described above. However, the disclosure is not limited thereto. According to an embodiment, the second value corresponding to the mirrored mode may be used as the default value. In this case, all the first memory devices 101a, 102a, . . . , etc. and the second memory devices 101b, 102b, . . . , etc. may operate in the mirrored mode during an initial time interval where the memory module 1000 is powered up.

In this case, assuming the memory module 1000-1 with the structure illustrated in FIG. 4, for the first memory devices 101a, 102a, . . . , etc. and the second memory devices 101b, 102b, . . . , etc. to perform the same operation depending on the CA signals, the operation mode of the second memory devices 101b, 102b, . . . , etc. may be changed from the mirrored mode to the standard mode.

To this end, the memory controller 800 may apply the fourth command to the memory module 1000-1. In this case, the fourth command may be a command for setting a value corresponding to the standard mode in the mirror information storage regions 101b_1, 102b_1, . . . , etc. of the second memory devices 101b, 102b, . . . , etc.

For example, the second command illustrated in FIG. 5 may be a command for setting a value corresponding to the mirrored mode in the mirror information storage regions 101b_1, 102b_1, . . . , etc. of the second memory devices 101b, 102b, . . . , etc.; in this case, the value corresponding to the mirrored mode may be a value of the CA13 bit, that is, “1”. Accordingly, a command which is implemented by changing only a value of the CA13 bit to “0” in the second command of FIG. 5 may be used as the fourth command as an example. When the fourth command is applied to the memory module 1000-1, a value corresponding to the standard mode may be set in the mirror information storage regions 101b_1, 102b_1, . . . , etc. of the second memory devices 101b, 102b, . . . , etc. The term “pin” used in the above description may be called a “ball”.

According to one or more embodiments of the disclosure, a mirror function may be implemented without a mirror pin. For example, according to one or more embodiments of the disclosure, a mirror function may be implemented without a mirror pin while maintaining a structure in which memory devices mounted on opposite surfaces of a circuit board to face away from each other share CA signals through vias. Accordingly, an existing pin for the mirror function may be used as a pin for any other purposes, such as an I/O pin or a ground pin. This may mean that the integrity of signal is improved. According to one or more embodiments of the disclosure, a mirror function may be implemented without a mirror pin.

While the disclosure has been described with reference to embodiments thereof, it will be apparent to those of ordinary skill in the art that various changes and modifications may be made thereto without departing from the spirit and scope of the disclosure as set forth in the following claims.

What is claimed is:

1. A memory module comprising:
a circuit board comprising a plurality of signal lines to which a command is applied; and
a first memory device mounted on a first surface of the circuit board, connected to the plurality of signal lines, comprising a first mode register, and configured to:
operate in a standard mode or a mirrored mode, based on a value set in the first mode register,
set a value corresponding to the mirrored mode in the first mode register, based on a first command applied to the plurality of signal lines,
wherein at least one bit of a plurality of command/address bits in the first command is swapped with at least one bit of a plurality of command/address bits in a second command.

2. The memory module of claim 1, wherein the first memory device is further configured to:
operate in the standard mode, based on a default value set in the first mode register; and
set the value corresponding to the mirrored mode in the first mode register based on the first command applied to the plurality of signal lines in the standard mode.

3. The memory module of claim 2, wherein the first memory device further comprises a nonvolatile memory region configured to store a value set in the first mode register during a power-up operation, and
wherein the nonvolatile memory region is configured to store the default value.

4. The memory module of claim 3, wherein, based on the value corresponding to the mirrored mode being set in the first mode register based on the first command, the first memory device is further configured to change the default value stored in the nonvolatile memory region to the value corresponding to the mirrored mode.

5. The memory module of claim 1, wherein, based on a third command being applied to the plurality of signal lines in the mirrored mode, the first memory device is further configured to:
receive a fourth command in which at least one bit of a plurality of command/address bits is swapped with at least one bit of the plurality of command/address bits in the third command; and
perform an operation corresponding to the third command by swapping the at least one bit of the plurality of command/address bits in the third command with the at least one bit of the plurality of command/address bits in the fourth command.

6. The memory module of claim 1, wherein the first memory device further comprises a plurality of pins respectively corresponding to the plurality of command/address bits,
wherein the plurality of pins comprises:
a first pin corresponding to a first command/address bit among the plurality of command/address bits; and
a second pin corresponding to a second command/address bit among the plurality of command/address bits,
wherein the circuit board comprises:
a first signal line corresponding to the first command/address bit; and
a second signal line corresponding to the second command/address bit,
wherein a value of the first command/address bit is applied to the second pin of the first memory device through the first signal line, and
wherein a value of the second command/address bit is applied to the first pin of the first memory device through the second signal line.

7. The memory module of claim 6, further comprising a second memory device mounted on a second surface of the circuit board to face away from the first memory device and comprising a second mode register,
wherein the second memory device comprises a plurality of pins respectively corresponding to the plurality of command/address bits,
wherein the first pin of the second memory device is connected to the second pin of the first memory device through a first via of the circuit board,
wherein the second pin of the second memory device is connected to the first pin of the first memory device through a second via of the circuit board,
wherein the value of the first command/address bit is applied to the first pin of the second memory device through the first signal line and the first via, and
wherein the value of the second command/address bit is applied to the second pin of the second memory device through the second signal line and the second via.

8. The memory module of claim 7, wherein the first command is applied in common to the first memory device and the second memory device,
wherein the first memory device is configured to receive the first command based on a value of a first chip select signal, and
wherein the second memory device is configured to ignore the first command based on a value of a second chip select signal.

9. The memory module of claim 6, wherein a value of the first command/address bit of the first command is identical to a value of the second command/address bit of the second command, and
wherein a value of the second command/address bit of the first command is identical to a value of the first command/address bit of the second command.

10. The memory module of claim 1, wherein the first command is a command in which a value of an even-numbered command/address bit of the second command and a value of an odd-numbered command/address bit of the second command, which is next to the even-numbered command/address bit and is higher than the even-numbered command/address bit, are swapped.

11. The memory module of claim 1, wherein the first memory device further comprises:
a command/address swap circuit configured to swap at least one bit of a plurality of command/address bits in an applied command, based on the value set in the first mode register,
wherein, based on a default value corresponding to the standard mode being set in the first mode register, the command/address swap circuit is further configured to maintain the at least one bit of the plurality of command/address bits in the applied command, and
wherein, based on the value corresponding to the mirrored mode being set in the first mode register, the command/address swap circuit is further configured to swap the at least one bit of the plurality of command/address bits in the applied command.

12. A memory system comprising:
a memory module comprising a first memory device mounted on a first surface of a circuit board; and
a memory controller operatively connected to the memory module,
wherein the first memory device comprises a first mode register and is configured to operate in a standard mode or a mirrored mode based on a value stored in the first mode register,
wherein the circuit board comprises a plurality of signal lines connected to the first memory device,
wherein the memory controller is configured to apply, to the plurality of signal lines, a first command for setting a value corresponding to the mirrored mode in the first mode register, and
wherein the first command is a command in which at least one bit of a plurality of command/address bits is swapped with at least one bit of a plurality of command/address bits in a second command.

13. The memory system of claim 12, wherein the first memory device is further configured to:
operate in the standard mode, based on a default value set in the first mode register; and
set the value corresponding to the mirrored mode in the first mode register, based on the first command applied to the plurality of signal lines in the standard mode.

14. The memory system of claim 12, wherein the memory controller is included in test equipment for the memory module.

15. The memory system of claim 12, wherein the memory module further comprises a serial presence detect (SPD) comprising information about the memory module,
wherein the memory controller is configured to identify a memory device to be used in the mirrored mode from among the first memory device and the second memory device, based on information received from the SPD.

16. The memory system of claim 12, wherein the first command is a command in which a value of an even-numbered command/address bit of the second command and a value of an odd-numbered command/address bit of the second command, which is next to the even-numbered command/address bit and is higher than the even-numbered command/address bit, are swapped.

17. A method of a memory module comprising a first memory device mounted on one surface of a circuit board, the method comprising:
operating, at the first memory device, in a standard mode, based on a default value set in a first mode register in the first memory device;
setting a value corresponding to a mirrored mode in the first mode register, based on a first command applied to a plurality of signal lines connected to the first memory device; and
operating, at the first memory device, in the mirrored mode, based on the value corresponding to the mirrored mode set in the first mode register,
wherein the circuit board comprises the plurality of signal lines, and
wherein the first command is a command in which at least one bit of a plurality of command/address bits is swapped with at least one bit of a plurality of command/address bits in a second command.

18. The method of claim 17, further comprising storing, in a nonvolatile memory region, a value set in the first mode register during a power-up operation, and storing, in the nonvolatile memory region, the default value.

19. The method of claim 18, further comprising changing the default value stored in the nonvolatile memory region of the first memory device to the value corresponding to the mirrored mode set in the first mode register.

20. The method of claim 17, further comprising:
applying a third command to the plurality of signal lines while the first memory device operates in the mirrored mode;
receiving, at the first memory device, a fourth command in which at least one bit of a plurality of command/address bits is swapped with at least one bit of a plurality of command/address bits in the third command; and
performing an operation corresponding to the third command by swapping the at least one bit of the plurality of command/address bits with the at least one bit of the plurality of command/address bits in the fourth command.
